(19) United States
(12) Patent Application Publication
(10) Pub. No.: US 2026/0082497 A1
(43) Pub. Date: Mar. 19, 2026

(54) ELECTRONIC DEVICE AND MANUFACTURING METHOD FOR THE SAME

(71) Applicant: Samsung Display Co., Ltd., Yongin-si (KR)

(72) Inventor: Katsuhiro YAMAMOTO, Yokohama-shi (JP)

(21) Appl. No.: 19/291,028

(22) Filed: Aug. 5, 2025

(30) Foreign Application Priority Data
Sep. 13, 2024 (JP) 2024-159462
Jan. 14, 2025 (JP) 2025-005003

(51) Int. Cl. H05K 5/03

(52) U.S. Cl. CPC H05K 5/03

(57) ABSTRACT

A method for manufacturing a display device including applying (e.g., depositing) a substrate, in which a first region and a second region around (e.g., surrounding) the first region are defined, on a stage is provided. The method includes forming an adhesion member on the substrate, wherein the forming of the adhesion member includes applying a first resin composition onto the substrate to overlap the first region and the second region, providing first light to cure the first resin composition, applying a second resin composition onto the cured first resin composition to overlap the second region, and providing second light to cure the second resin composition, and each of the first resin composition and the second resin composition has a viscosity of at least about 10 millipascal second (mPa·s) (or greater) and at most about 30 mPa·s (or less) at about 25° C.

### CROSS-REFERENCE TO RELATED APPLICATIONS

This application claims priority to and the benefit of Japanese Patent Application No. 2024-159462, filed on Sep. 13, 2024, and Japanese Patent Application No. 2025-005003, filed on Jan. 14, 2025, in the Japan Patent Office, the entire contents of each of the aforementioned applications are incorporated herein by reference.

### BACKGROUND

One or more embodiments of the present disclosure relate to an electronic device including an adhesion member and a manufacturing method for the electronic device.

One or more suitable display devices used for multi-media apparatuses—such as televisions, mobile phones, tablet computers, navigation systems, and/or game consoles—are under continuous development. For example, to enhance portability and/or user convenience, flexible display members that allow folding, bending, or rolling are being actively developed.

For each component (member) utilized in such flexible display devices, it is desired or even necessary to ensure reliability during folding and/or bending operations. In particular, adhesive resins utilized to form adhesion layers in these devices should exhibit enhanced (excellent) coating properties and be suitable for application to various components of the display device in different configurations.

### SUMMARY

One or more aspects of embodiments of the present disclosure are directed toward a manufacturing method for an adhesion member including two or more cycles of application processes, and a manufacturing method for a display device including the adhesion member. For example, the present disclosure is directed toward a method of manufacturing an adhesion member, the method including two or more cycles of application processes. The present disclosure is also directed toward a method of manufacturing a display device that includes the adhesion member.

One or more aspects of embodiments of the present disclosure are directed toward an electronic device including the adhesion member as formed from the manufacturing method for the display device. For example, the present disclosure is directed toward an electronic device that includes the adhesion member formed by the aforementioned manufacturing method for the display device.

Additional aspects will be set forth in part in the description which follows and, in part, will be apparent from the description, or may be learned by practice of the presented embodiments of the disclosure.

One or more embodiments of the disclosure provides a manufacturing method for a display device including applying (e.g., depositing) a substrate, in which a first region and a second region around (e.g., surrounding) the first region are defined, on a stage, (e.g., applying or depositing a substrate on a stage, the substrate having a first region and a second region around the first region). The manufacturing method includes forming an adhesion member on the substrate, wherein the forming of the adhesion member includes applying a first resin composition onto the substrate to overlap the first region and the second region, providing a first light to cure the first resin composition, (e.g., to provide a cured first resin composition), applying a second resin composition onto the cured first resin composition to overlap the second region, and providing second light to cure the second resin composition, and each of the first resin composition and the second resin composition has a viscosity of at least about 10 millipascal second (mPa·s) (e.g., or greater) and at most about 30 mPa·s (e.g., or less) at about 25° C.

In one or more embodiments, in the applying of the first resin composition, a first application amount of the first resin composition to be applied to the first region may be more (larger) than a second application amount of the first resin composition to be applied to the second region.

In one or more embodiments, the second region of the substrate may be divided into at least two (e.g., two or more) first unit regions, each having a different application amount of the first resin composition.

In one or more embodiments, the second region of the substrate may be divided into a (1-1)-th unit region that is adjacent to the first region and around (e.g., surrounding) the first region, and a (1-2)-th unit region spaced and/or apart (e.g., spaced apart or separated) from the first region with the (1-1)-th unit region therebetween and around (e.g., surrounding) the (1-1)-th unit region, (e.g., the (1-1)-th unit region being between the first region and the (1-2)-th unit region).

In one or more embodiments, an application amount of the first resin composition to be applied to the (1-1)-th unit region may be less (smaller) than an application amount of the first resin composition to be applied to the (1-2)-th unit region.

In one or more embodiments, before the applying of the first resin composition, the forming of the adhesion member may further include forming the substrate into a bitmap including m pixels in a first direction and g pixels in a second direction crossing the first direction, dividing the second region into the two or more first unit regions on the bitmap, and setting an application amount of the first resin composition for each of the first region and the first unit regions.

In one or more embodiments, an average application amount of the first resin composition in the first unit regions may be calculated by Expression 1, and may be about at least 50 (e.g., or greater) and at most about 85 (e.g., or less).

$$[ ( X 1 \times A 1 ) + … ( Xn \times An ) ] \div ( A 1 + … An ) \qquad Expression 1$$

wherein, in Expression 1, X1 to Xn may each independently be an application amount of the first resin composition, respectively, for a 1st first unit region to an n-th first unit region, e.g., if (e.g., when) the application amount of the first resin composition to be applied to the first region is 100, and n may be an integer of 2 or greater, and A1 to An may each independently be a number of pixels, respectively, in the 1st first unit region to the n-th first unit region, and n may be an integer of 2 or greater.

In one or more embodiments, before the applying of the second resin composition, the forming of the adhesion member may further include forming the substrate into a bitmap including p pixels in a first direction, and q pixels in a second direction crossing the first direction, dividing the second region into at least two (e.g., two or more) second unit regions on the bitmap, and setting an application amount for the second unit regions.

In one or more embodiments, the second unit region may include a (2-1)-th unit region adjacent to the first region and around (e.g., surrounding) the first region, and a (2-2)-th unit region spaced and/or apart (e.g., spaced apart or separated) from the first region with the (2-1)-th unit region therebetween and around (e.g., surrounding) the (2-1)-th unit region, (e.g., the (2-1)-th unit region being between the first region and the (2-2)-th unit region), and an application amount of the second resin composition to be applied to the (2-1)-th unit region may be different from an application amount of the second resin composition to be applied to the (2-2)-th unit region.

In one or more embodiments, the application amount of the second resin composition to be applied to the (2-1)-th unit region may be larger than the application amount of the second resin composition to be applied to the (2-2)-th unit region.

In one or more embodiments, the adhesion member may include a peak part which overlaps the second region and at which a height from a lower surface of the adhesion member to an upper surface of the adhesion member is maximum in a thickness direction, and a horizontal distance from an edge of the adhesion member to the peak part may be at least about 300 micrometer (μm) (or greater) and at most about 600 μm (or less).

In one or more embodiments, in the forming of the adhesion member, a temperature at the stage may be at least about 20° C. (or higher) and at most about 30° C. (or lower).

In one or more embodiments, the first resin composition and the second resin composition may be applied through inkjet printing.

In one or more embodiments, the second region may have a width of at most about 3 millimeter (mm) (or less).

In one or more embodiments, in the applying of the second resin composition, the second resin composition applied onto the substrate may not overlap the first region.

In one or more embodiments of the disclosure, a manufacturing method for a display device includes preparing a display panel in which a first region and a second region around (e.g., surrounding) the first region are defined, (e.g., a display panel including a first region and a second region around the first region), forming an adhesion member on the display panel using an inkjet process (manner), and bonding a window onto the display panel through the adhesion member, the forming of the adhesion member includes applying a first resin composition onto the display panel, curing the first resin composition to form a preliminary adhesion member, applying a second resin composition onto the preliminary adhesion member along an edge of the preliminary adhesion member, and curing the second resin composition, and each of the first resin composition and the second resin composition has a viscosity of at least about 10 mPa·s (or greater) and at most about 30 mPa·s (or less) at about 25° C.

In one or more embodiments, in the applying of the first resin composition, an application amount of the first resin composition, sprayed from an inkjet head, may be controlled or selected, so that the first resin composition may be applied onto the first region of the display panel in a first application amount, and the first resin composition may be applied onto the second region of the display panel in a second application amount that is different from the first application amount.

In one or more embodiments, before the applying of the first resin composition, the forming of the adhesion member may further include dividing the second region into at least two (e.g., two or more) first unit regions, each having a different application amount of the first resin composition, and setting an application amount of the first resin composition for each of the first region and the first unit regions, and in the applying of the first resin composition (e.g., onto the display panel), the first resin composition may be applied onto the first region and the first unit regions according to the set application amount.

In one or more embodiments, the edge of the preliminary adhesion member may correspond to the second region of the display panel.

In one or more embodiments of the disclosure, an electronic device includes a display panel in which a first region and a second region around (e.g., surrounding) the first region are defined, a window arranged on the display panel, and an adhesion member arranged between the display panel and the window, and including (e.g., derived from) a resin composition having a viscosity of at least about 10 mPa·s (or greater) and at most about 30 mPa·s (or less) at about 25° C., and the adhesion member includes a peak part which overlaps the second region and at which a height from a lower surface of the adhesion member to an upper surface of the adhesion member is maximum in a thickness direction, and a horizontal distance from an edge of the adhesion member to the peak part is at least about 300 μm (or greater) and at most about 600 μm (or less).

In one or more embodiments, the electronic device may be selected from among a large-size display device including a television, a monitor, and an outdoor billboard, and a small- and medium-size display device including a personal computer, a laptop computer, a personal digital assistant, a display device for a vehicle, a game console, a portable electronic device, a camera, and a (e.g., any suitable) combination thereof.

In one or more embodiments, the electronic device may further include at least one of a processor, a memory, or a power module.

For example, an embodiment of the present disclosure provides a method for manufacturing a display device that includes forming an adhesion member on a substrate or display panel having a defined first region and a surrounding second region. The method involves sequentially applying and curing a first resin composition and a second resin composition—each having a viscosity of about 10 to 30 mPa·s at 25° C.—using inkjet printing. The first resin is applied to both the first and second regions, while the second resin is applied only to the second region, with application amounts controlled per region and sub-region. The second region may be divided into multiple unit regions (e.g., (1-1), (1-2), (2-1), (2-2)), each with distinct resin application amounts, determined using bitmap mapping of pixel arrays. The method may include calculating average application amounts utilizing weighted expressions and forming a peak part in the adhesion member with a maximum height in the thickness direction and a horizontal distance of about 300-600 μm from the edge. The adhesion member may serve to bond a window to the display panel, and the edge of the preliminary adhesion member may correspond to the second region. The resulting electronic device includes the display panel, the window, and the adhesion member, and may further include components such as a processor, memory, and/or power module. The device may be a large-size display (e.g., television, monitor, or billboard) or a small- to medium-size device (e.g., laptop, PDA, vehicle display, game console, camera, or portable electronic device).

### BRIEF DESCRIPTION OF THE DRAWINGS

The accompanying drawings are included to provide a further understanding of the preceding and other aspects, features, and advantages of certain embodiments of the disclosure, and are incorporated in and constitute a part of this specification. The drawings illustrate embodiments of the disclosure and, together with the description, serve to explain principles of the disclosure. In the drawings:

FIG. 1 is a perspective view of a display device according to one or more embodiments of the disclosure;

FIG. 2 is a drawing illustrating a folded state of the display device illustrated in FIG. 1;

FIG. 3 is a perspective view of a display device according to one or more embodiments of the disclosure;

FIG. 4 is a drawing illustrating a folded state of the display device illustrated in FIG. 3;

FIG. 5 is a perspective view of a display device according to one or more embodiments of the disclosure;

FIG. 6 is an exploded perspective view of a display device according to one or more embodiments of the disclosure;

FIG. 7 is a cross-sectional view of a display device according to one or more embodiments of the disclosure;

FIG. 8 is a cross-sectional view of a display device according to one or more embodiments of the disclosure;

FIG. 9 is a cross-sectional view of a display device according to one or more embodiments of the disclosure;

FIG. 10 is a block diagram of an electronic device according to one or more embodiments;

FIG. 11 shows schematic views of an electronic device according to one or more suitable embodiments;

FIG. 12A is a flow chart of a manufacturing method for a display device according to one or more embodiments of the disclosure;

FIG. 12B is a flow chart detailing a step (e.g., act or task) of forming an adhesion member in a manufacturing method for a display device according to one or more embodiments of the disclosure;

FIGS. 13A-13K are drawings schematically illustrating a step (e.g., act or task) of forming an adhesion member according to one or more embodiments of the disclosure; and

FIGS. 14A-14C are drawings schematically illustrating a step (e.g., act or task) of forming an adhesion member according to one or more embodiments of the disclosure.

### DETAILED DESCRIPTION

The disclosure may have one or more suitable modifications and forms, and specific embodiments thereof are illustrated in the drawings and described in more detail in this specification. However, this is not intended to limit the disclosure to a specific disclosure form, but should be understood to include all modifications, equivalents, or substitutes falling within the spirit and technical scope of the disclosure.

Expressions such as “at least one of,” “one of,” “selected from,” and “selected from among,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

In this specification, it will be understood that when an element (or a region, a layer, a portion, and/or the like) is referred to as being “on”, “connected to” or “coupled to” another element, it may be directly arranged on, connected to, or coupled to the other element, or other elements may be arranged therebetween.

In this application, “directly arranged” may refer to that there is no additional layer, film, region, substrate, and/or the like existing between one part of a layer, film, region, substrate, and/or the like and another part. For example, “directly arranged” may refer to being arranged between two layers or two members without using an additional member such as an adhesion member.

Reference will be made in more detail to one or more embodiments, examples of which are illustrated in the accompanying drawings, wherein like reference numerals or symbols refer to like elements throughout, and duplicative descriptions thereof may not be provided. In this regard, the present embodiments may have different forms and should not be construed as being limited to the descriptions set forth herein. Accordingly, one or more embodiments are merely described by referring to the drawings, to explain aspects of the present description. In the drawings, the thickness, ratio, and size of the elements are exaggerated for effectively describing the technical contents. For example, because sizes and thicknesses of components in the drawings are arbitrarily illustrated for convenience of explanation, the following embodiments are not limited thereto.

As used herein, the term “and/or” includes any and all combinations of one or more of the associated listed elements.

It will be understood that, although the terms “first”, “second”, and/or the like may be used herein to describe one or more suitable elements, the elements are not to be limited by these terms. These terms are only used to distinguish one element from another element. For instance, a first element discussed could be termed a second element, without departing from the scope of the disclosure. Similarly, a second element could be termed a first element. In this specification, the singular expressions “a”, “an” and “the” are intended to include the plural forms as well, unless the context clearly indicates otherwise.

In some embodiments, the terms “below”, “under”, “on the lower side”, “above”, “over”, “on the upper side”, and/or the like may be used to describe the relationships between the elements illustrated in the drawings. These terms are relative concepts and are described on the basis of the directions indicated in the drawings. In this specification, “arranged on” may refer to being arranged not only on an upper part of one member but also being arranged on a lower part thereof. For example, if the device in the drawings is turned over, elements described as “below” or “beneath” other elements or features would then be oriented “above” or “over” the other elements or features. Thus, the term “below” may encompass both (e.g., simultaneously) an orientation of above and below. The device may be otherwise oriented (rotated 90 degrees or at other orientations), and the spatially relative descriptors used herein should be interpreted accordingly.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “comprise, include, have,” “comprises, includes, has,” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

In this context, “consisting essentially of” indicates that any additional components will not materially affect the chemical, physical, optical or electrical properties of the semiconductor film.

As used in this specification, the phrase “on a plane” or “in plan view” refers to a top-down view of a target portion, as if viewed from directly above. The phrase “on a cross-section” or “in cross-sectional view” refers to a side view of a target portion, as seen along a vertical plane that cuts through the structure. Hereinafter, with reference to the drawings, a resin composition and an adhesion member according to one or more embodiments of the disclosure, and a display device according to one or more embodiments will be described.

### Display Device

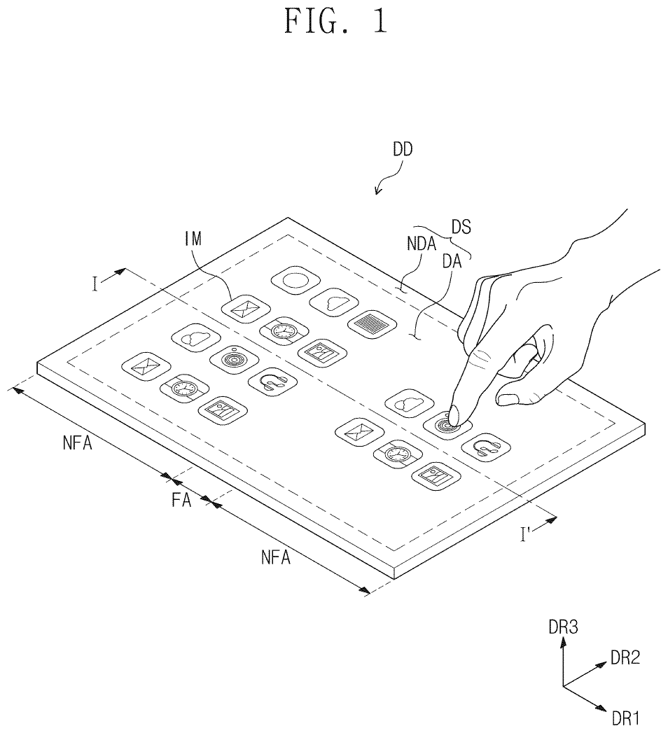

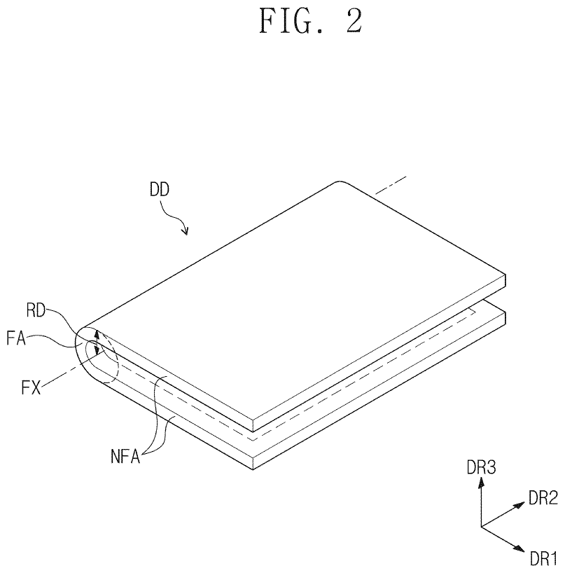

FIG. 1 is a perspective view of a display device according to one or more embodiments. FIG. 2 is a drawing illustrating a folded state of the display device illustrated in FIG. 1.

Referring to FIG. 1, a display device DD according to one or more embodiments may have a rectangular shape having long sides extending in a first direction DR1 and short sides extending in a second direction DR2 crossing the first direction DR1. However, one or more embodiments are not limited thereto, and the display device DD may have one or more suitable shapes such as a circular shape and a polygonal shape on a plane. The display device DD may be a flexible display device.

In the display device DD according to one or more embodiments, a display surface DS where an image IM is displayed may be parallel to a surface defined by the first direction DR1 and the second direction DR2. The normal direction of the display surface DS, which is the thickness direction of the display device DD, is indicated by a third direction DR3. A front surface (or upper surface) and a rear surface (or lower surface) of each of members are distinguished on the basis of the third direction DR3. However, directions indicated by the first to third directions DR1, DR2, and DR3 may be relative concepts and may thus be changed to other directions.

The display device DD according to one or more embodiments may include at least one folding region FA. Referring to FIGS. 1 and 2, the display device DD may include a folding region FA and a plurality of non-folding regions NFA. The folding region FA may be arranged between the non-folding regions NFA, and the folding region FA and the non-folding regions NFA may be arranged adjacent to each other in the first direction DR1.

The folding region FA may be a portion deformable to a folded state with respect to a folding axis FX extending in the second direction DR2 that is one direction. The folding region FA may have a radius of curvature RD of about 5 millimeter (mm) or less.

FIGS. 1 and 2 illustrate one folding region FA and two non-folding regions NFA as an example, but the number of each of the folding region FA and the non-folding regions NFA is not limited thereto. For example, the display device DD may include a plurality of non-folding regions NFA, more than 2, and may include a plurality of folding regions FA arranged between the non-folding regions NFA.

In the display device DD according to one or more embodiments, the non-folding regions NFA may be arranged symmetrically with each other with respect to the folding region FA. However, one or more embodiments is not limited thereto, and the folding region FA may be arranged between the non-folding regions NFA, but the areas of two non-folding regions NFA opposite to (e.g., facing) each other, with respect to the folding region FA, may be different from each other.

The display surface DS of the display device DD may include a display region DA and a non-display region NDA around the display region DA. The display region DA may display an image, and the non-display region NDA may not display an image. The non-display region NDA may surround the display region DA, and define a border of the display device DD.

Referring to FIG. 2, the display device DD may be a foldable display device DD which is folded or unfolded. For example, the folding region FA may be bent with respect to the folding axis FX parallel to the second direction DR2, so that the display device DD may be folded. The folding axis FX may be defined as a short axis parallel to the short side of the display device DD.

If (e.g., when) the display device DD is folded, the non-folding regions NFA may face each other, and the display device DD may be in-folded such that the display surface DS is not exposed to the outside. However, one or more embodiments is not limited thereto, and the display device DD may be out-folded such that the display surface DS is exposed to the outside.

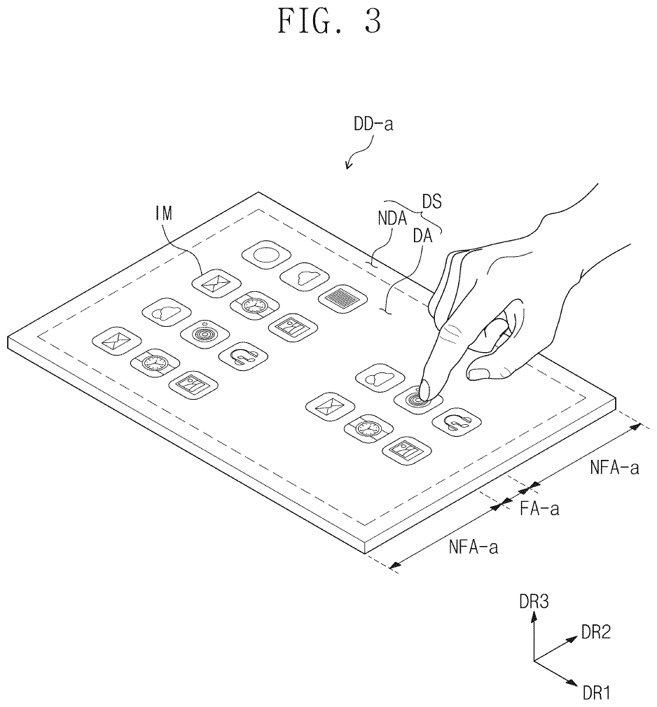

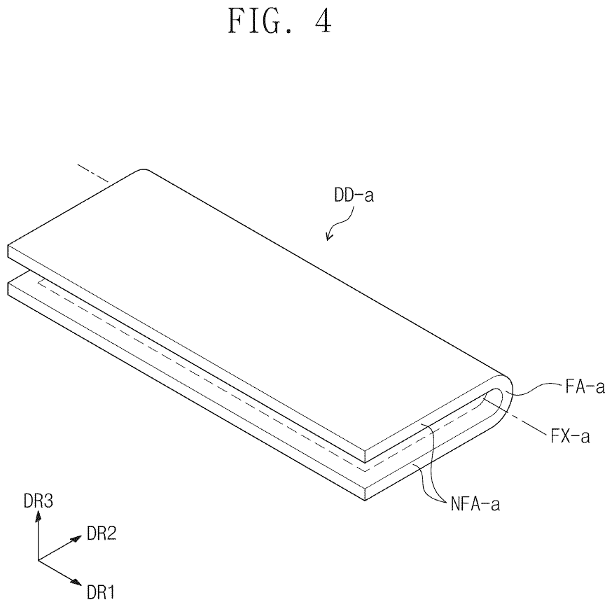

FIG. 3 is a perspective view of a display device according to one or more embodiments. FIG. 4 is a drawing illustrating a folded state of the display device illustrated in FIG. 3.

Except for a folding operation, a display device DD-a illustrated in FIG. 3 has substantially the same configuration as that of the display device DD illustrated in FIG. 1. Therefore, in the description on the display device DD-a illustrated in FIGS. 3 and 4, the folding operation is mainly described.

Referring to FIGS. 3 and 4, the display device DD-a may include a folding region FA-a and a plurality of non-folding regions NFA-a. The folding region FA-a may be arranged between the non-folding regions NFA-a, and the folding region FA-a and the non-folding regions NFA-a may be arranged adjacent to each other in a second direction DR2.

The folding region FA-a may be bent with respect to a folding axis FX-a parallel to a first direction DR1, so that the display device DD-a may be folded. The folding axis FX-a may be defined as a long axis parallel to a long side of the display device DD-a. The display device DD illustrated in FIG. 1 may be folded with respect to the short axis, and on the contrary, the display device DD-a illustrated in FIG. 3 may be folded with respect to the long axis. FIG. 4 illustrates that the display device DD-a is in-folded such that the display surface DS is not exposed to the outside, but one or more embodiments is not limited thereto, and the display device DD-a may be folded with respect to the long axis and may be out-folded.

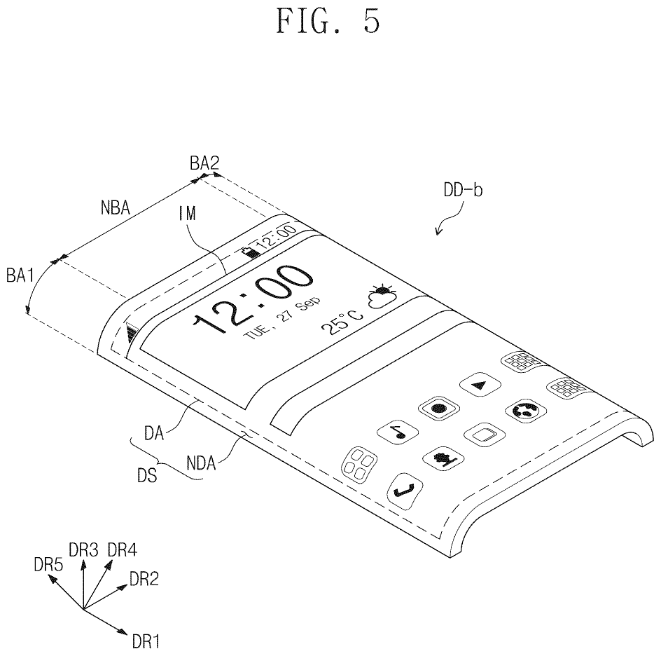

FIG. 5 is a perspective view of a display device according to one or more embodiments. A display device DD-b according to one or more embodiments may include a bending region BA1 and/or BA2 and a non-bending region NBA, and the bending region BA1 and/or BA2 may be bent from one side of the non-bending region NBA.

Referring to FIG. 5, the display device DD-b according to one or more embodiments may include the non-bending region NBA where an image IM is displayed on a front surface, and a first bending region BA1 and a second bending region BA2 where the image IM is displayed on a side surface. The first bending region BA1 and the second bending region BA2 may be bent from respective sides of the non-bending region NBA.

Referring to FIG. 5, the image IM may be provided toward a third direction DR3, which is to a front surface of the display device DD-b, in the non-bending region NBA, and the image may be provided toward a fifth direction DR5 in the first bending region BA1, and provided toward a fourth direction DR4 in the second bending region BA2. The fourth direction DR4 and the fifth direction DR5 may each be a direction crossing the first to third directions DR1, DR2, and DR3. However, directions indicated by the first to fifth directions DR1 to DR5 may be relative concepts, and not limited to the relationship of the directions illustrated in the drawing.

The display device DD-b according to one or more embodiments may be a bending display device including the non-bending region NBA and the bending regions BA1 and BA2 arranged on respective sides of the non-bending region NBA. The display device according to one or more embodiments may be a bending display device including one non-bending region and one bending region. Accordingly, the bending region may be provided bent from only one side of the non-bending region.

With reference to FIGS. 1 to 5 previously described, the foldable display device, the bending display device, and/or the like are described, but one or more embodiments is not limited thereto. The display device according to one or more embodiments may also be a rollable display device, a flat rigid display device, or a curved rigid display device.

Hereinafter, in the description on the display device according to one or more embodiments, the display device DD is folded with respect to a short axis, but one or more embodiments is not limited thereto, and in the contents to be described in more detail, not only the display device DD-a folded with respect to a long axis and the display device DD-b including a bending region, but also display devices in one or more suitable forms may be also applied.

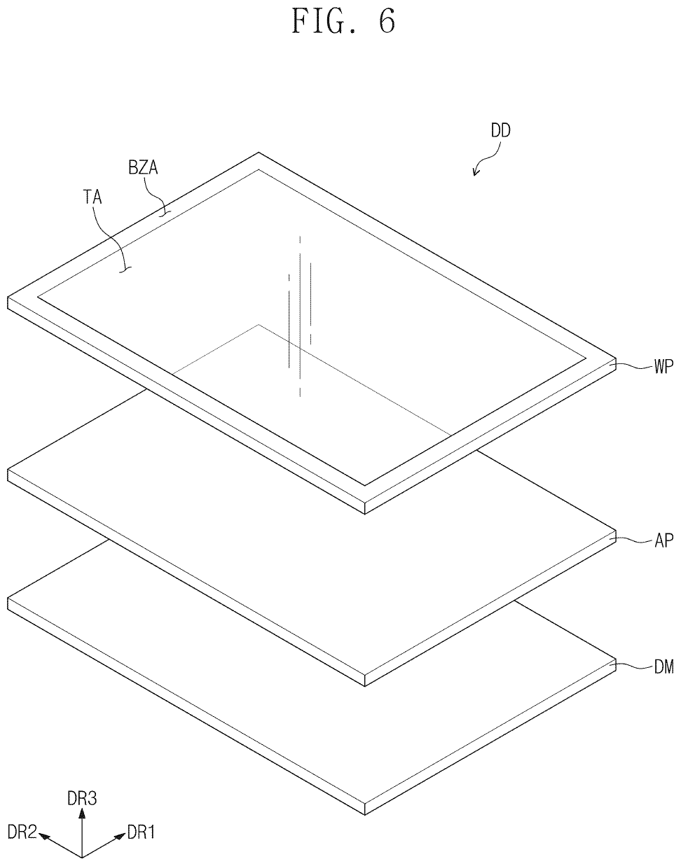

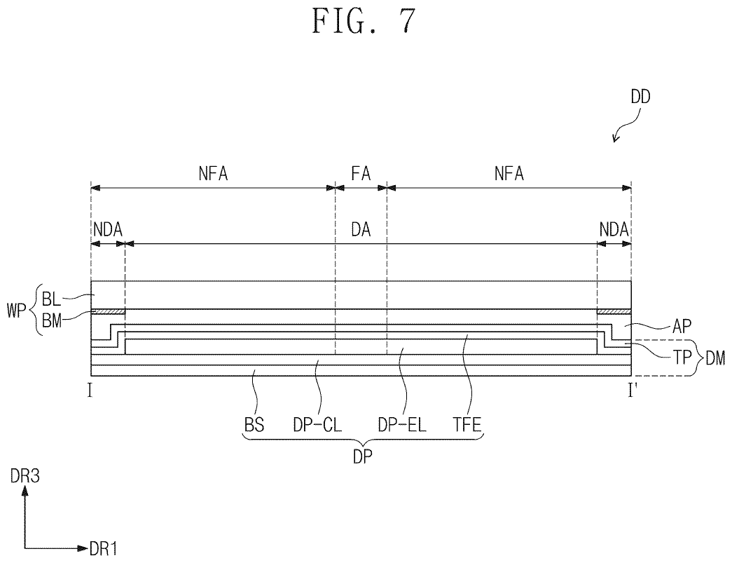

FIG. 6 is an exploded perspective view of a display device DD according to one or more embodiments. FIG. 7 is a cross-sectional view of a display device DD according to one or more embodiments. FIG. 7 may be a cross-sectional view of a portion corresponding to line I-I′ of FIG. 1.

The display device DD according to one or more embodiments may include a display module DM and a window WP arranged on the display module DM. In the display device DD according to one or more embodiments, the display module DM may include a display panel DP containing a display element layer DP-EL and an input-sensing part TP arranged on the display panel DP. The display device DD according to one or more embodiments may include an adhesion member AP arranged between the display panel DP and the window WP. For example, in the display device DD according to one or more embodiments, the adhesion member AP may be arranged between the input-sensing part TP and the window WP. The adhesion member AP may be an optically clear adhesive (OCA) film, or an optically clear adhesive resin (OCR) layer.

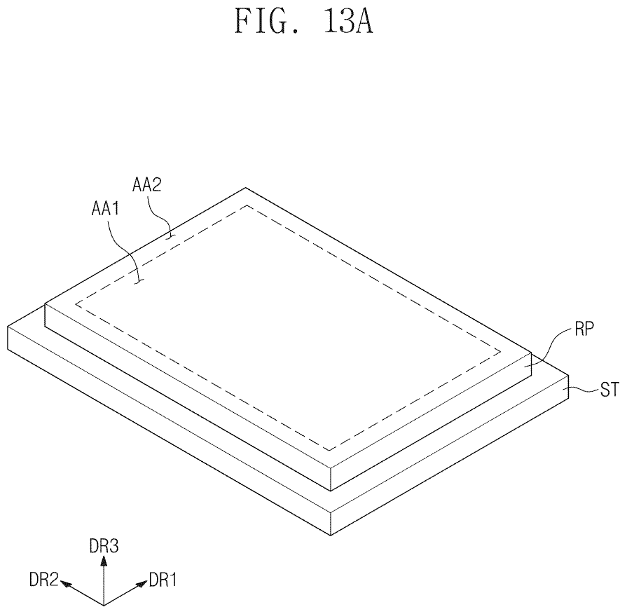

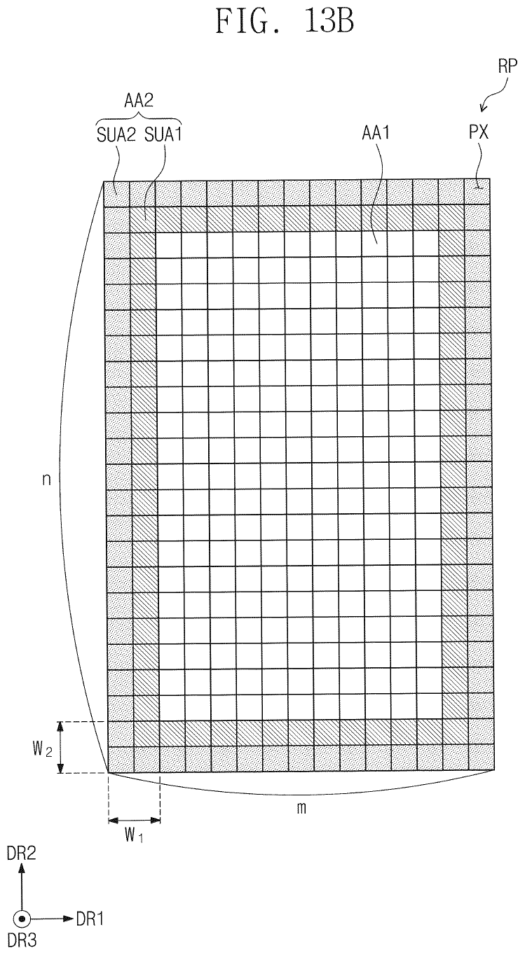

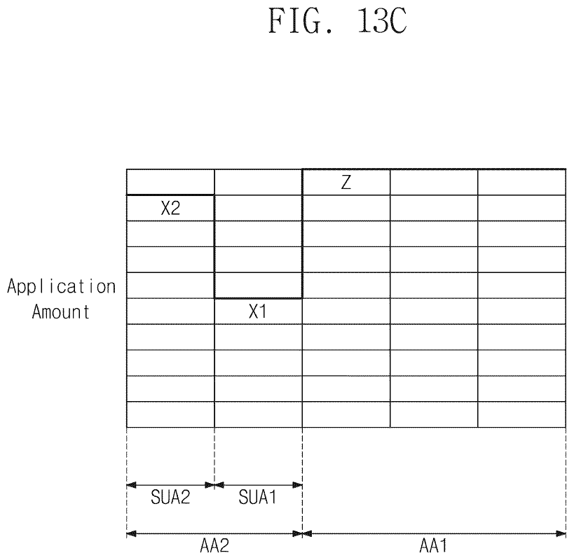

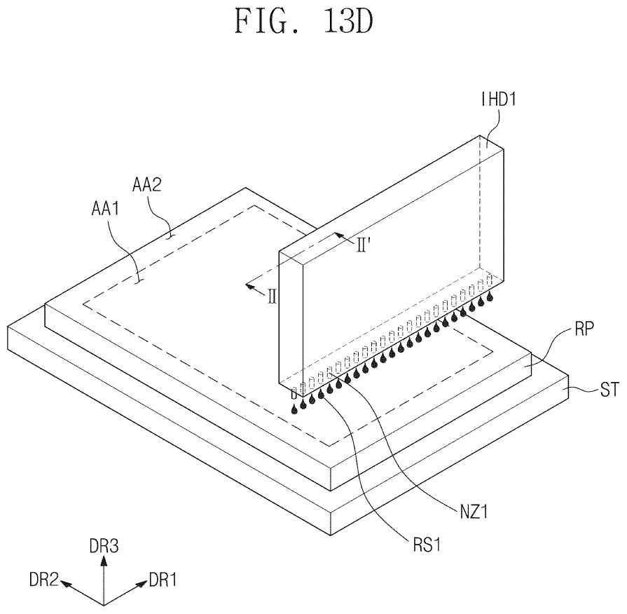

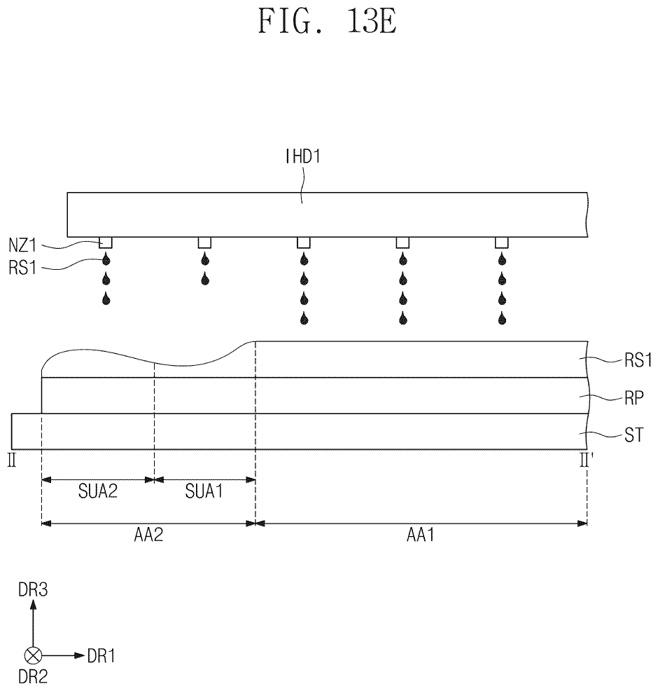

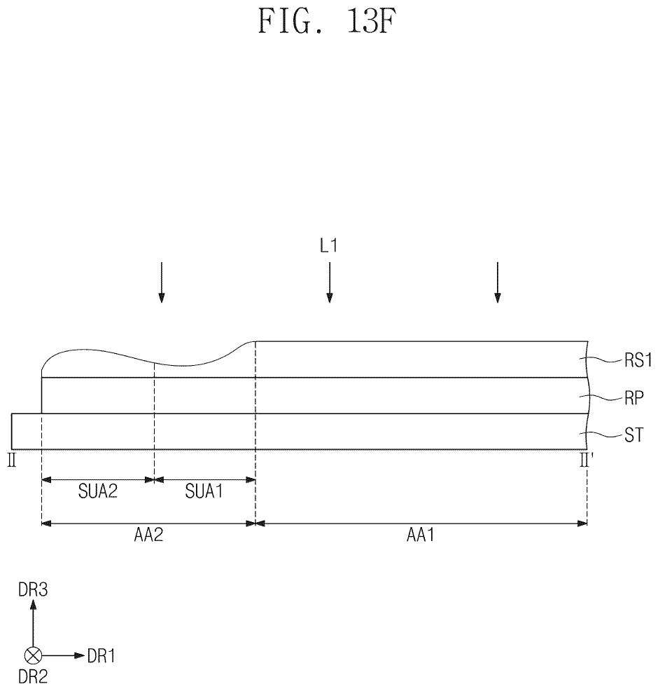

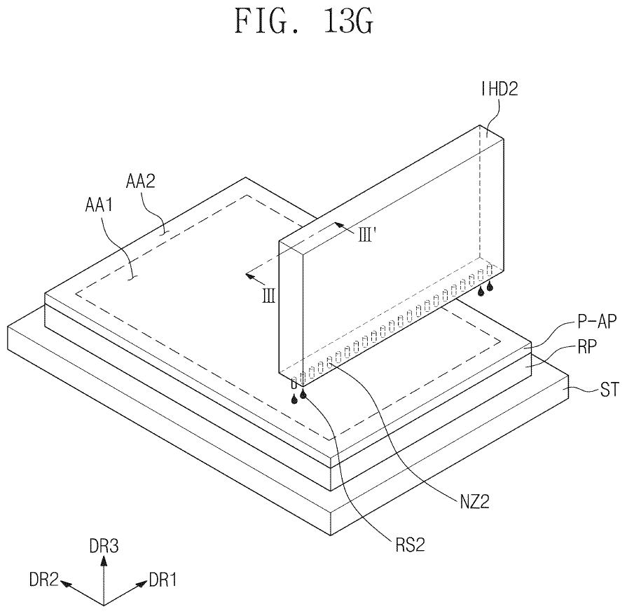

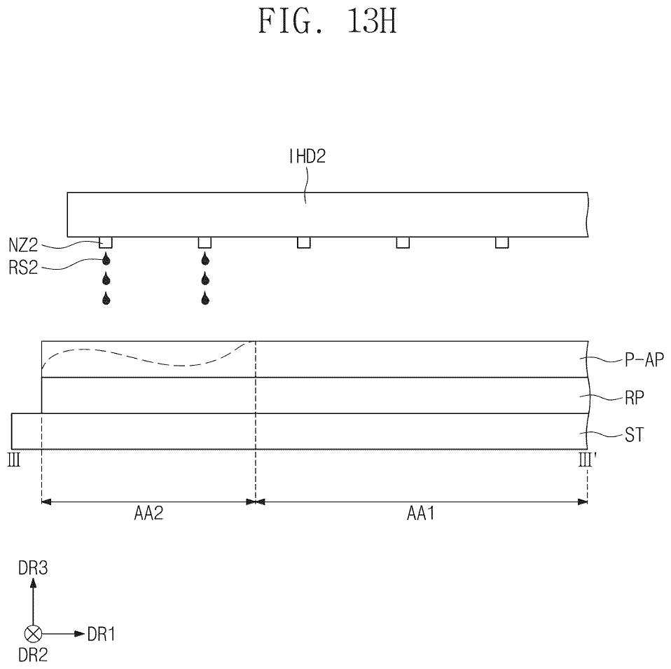

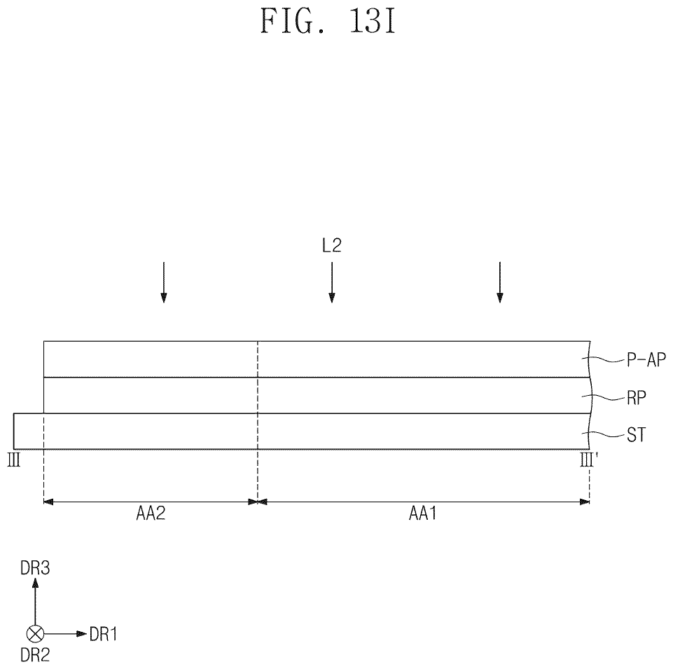

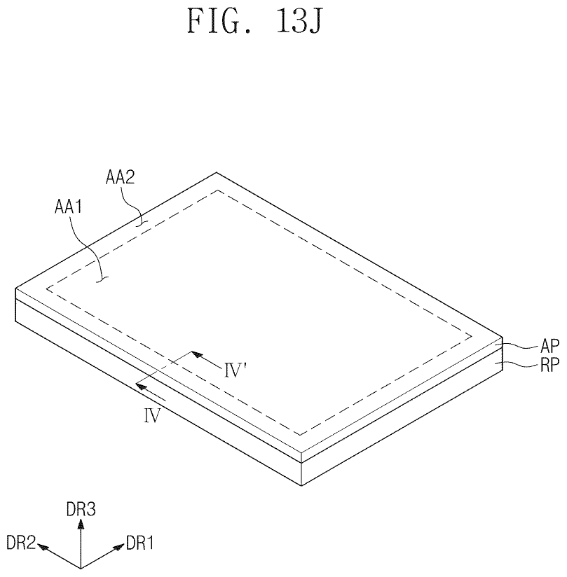

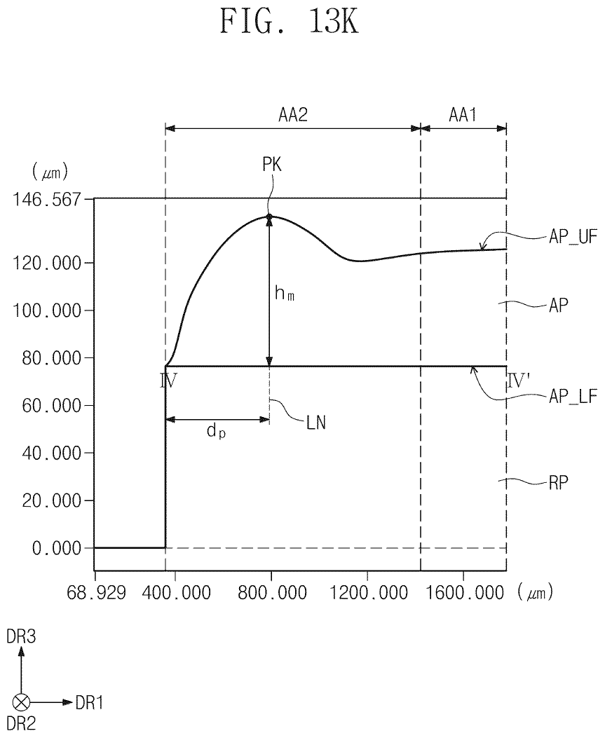

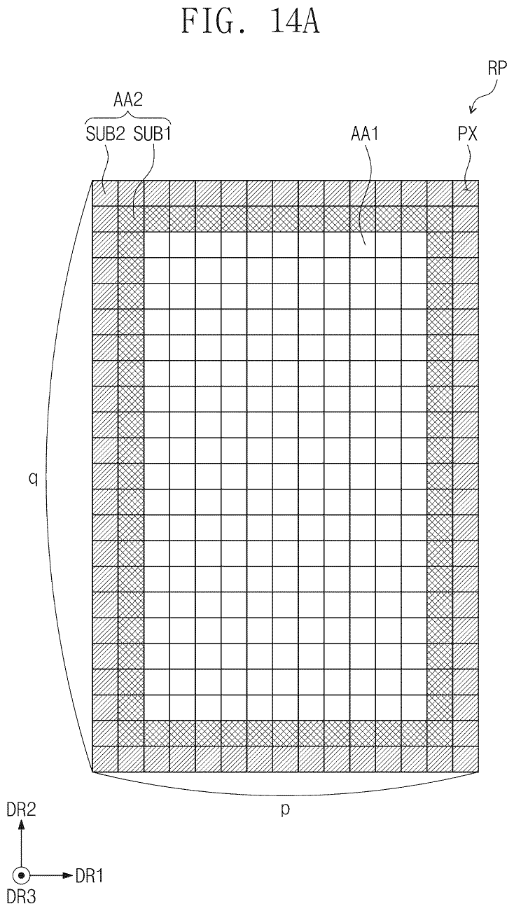

The adhesion member AP may be formed from a manufacturing method for an adhesion member according to one or more embodiments to be described in more detail. The adhesion member AP may be formed from a resin composition RS1 and RS2 (see FIGS. 13D and 13G) to be described later. The adhesion member AP may include a polymer derived from the resin composition RS1 and RS2 (see FIGS. 13D and 13G) to be described in more detail. A liquid resin composition may be cured by irradiation of UV rays, and after the curing with UV rays, the liquid resin composition may be provided in the form of a film or thin film. The resin composition, which forms the adhesion member AP through a polymerization reaction by a photoinitiator, may have a viscosity of at least about 10 millipascal second (mPa·s) (or greater) and at most about 30 mPa·s (or less) at about 20° C. or higher and about 30° C. or lower if (e.g., when) the viscosity is measured in a JIS K 2283 method.

The display panel DP may include a base substrate BS, a circuit layer DP-CL arranged on the base substrate BS, a display element layer DP-EL arranged on the circuit layer DP-CL, and an encapsulation layer TFE covering the display element layer DP-EL. For example, the display panel DP may include a plurality of organic light-emitting elements or a plurality of quantum-dot light-emitting elements on the display element layer DP-EL.

Configuration of the display panel DP, illustrated in FIG. 7, and/or the like, is an example, and the configuration of the display panel DP is not limited to what is illustrated in FIG. 7, and/or the like. For example, the display panel DP may include a liquid crystal display element, and in this case, the encapsulation layer TFE may not be provided.

The input-sensing part TP may be arranged on the display panel DP. For example, the input-sensing part TP may be directly arranged on the encapsulation layer TFE of the display panel DP. The input-sensing part TP may detect an external input and covert the external input into a set or predetermined input signal, and may provide the input signal to the display panel DP. For example, in the display device DD according to one or more embodiments, the input-sensing part TP may be a touch-sensing part which detects a touch. The input-sensing part TP may recognize a direct touch of a user, an indirect touch of a user, a direct touch of an aspect, an indirect touch of an aspect, and/or the like. The input-sensing part TP may detect at least one of a position of a touch or a strength (pressure) of the touch applied from the outside. The input-sensing part TP according to one or more embodiments of the disclosure may have one or more suitable structures or may include one or more suitable materials, and is not limited to any one or more embodiments. The input-sensing part TP may include a plurality of sensing electrodes for detecting an external input. The sensing electrodes may detect the external input in a capacitance manner. The display panel DP may receive input signals from the input-sensing part TP, and may generate a movie corresponding to the input signals.

The window WP may protect the display panel DP, the input-sensing part TP, and/or the like. The image IM generated in the display panel DP may penetrate the window WP to be provided to a user. The window WP may provide a touch surface of the display device DD. In the display device DD including a folding region FA, the window WP may be a flexible window.

The window WP may include a base layer BL and a printed layer BM. The window WP may include a transmission region TA and a bezel region BZA. A front surface of the window WP, including the transmission region TA and the bezel region BZA, corresponds to a front surface of the display device DD.

The transmission region TA may be an optically transparent region. The bezel region BZA may be a region which is relatively low in light transmittance, compared to the transmission region TA. The bezel region BZA may have a set or predetermined color. The bezel region BZA may be adjacent to the transmission region TA, and may surround the transmission region TA. The bezel region BZA may define a shape of the transmission region TA. However, one or more embodiments is not limited to what is illustrated in the drawing, and the bezel region BZA may also be arranged adjacent only to one side of the transmission region TA, and one portion thereof may also not be provided.

The base layer BL may be a glass or plastic substrate. For example, a reinforced glass substrate may be used for the base layer BL. In one or more embodiments, the base layer BL may include a polymer resin having flexibility. For example, the base layer BL may be made of polyimide, polyacrylate, polymethylmethacrylate, polycarbonate, polyethylene naphthalate, polyvinylidene chloride, polyvinylidene difluoride, polystyrene, an ethylene vinyl alcohol copolymer, or a combination thereof. However, one or more embodiments is not limited thereto, and any general form suitable as the base layer BL of the window WP in the relevant art may be used without limitation.

The printed layer BM may be arranged on one surface of the base layer BL. In one or more embodiments, the printed layer BM may be provided onto a lower surface of the base layer BL adjacent to the display module DM. The printed layer BM may be arranged on a boundary region of the base layer BL. The printed layer BM may be an ink-printed layer. In some embodiments, the printed layer BM may be a layer including pigment or dye. In the window WP, the bezel region BZA may be a portion where the printed layer BM is provided.

The window WP may further include at least one functional layer provided onto the base layer BL. For example, the functional layer may be a hard-coating layer, an anti-fingerprint coating layer, and/or the like, but one or more embodiments is not limited thereto.

The adhesion member AP included in the display device DD according to one or more embodiments may be provided onto one surface of the window WP or one surface of the display module DM in a state of a liquid resin composition, and may be provided by curing the provided liquid resin composition with UV rays. Unlike this, the adhesion member AP may be provided by curing the liquid resin composition with UV rays in a separate process, and laminating one surface of the adhesion member AP cured in the form of an adhesive film on one surface of the window WP or one surface of the display module DM, and bonding the other one surface of the adhesion member AP to one surface of the window WP or one surface of the display module DM that is not bonded. The adhesion member AP may have a thickness of at least about 50 micrometer (μm) (or greater) and at most about 200 μm (or less). For example, the adhesion member AP may have a thickness of at least about 50 μm (or greater) and at most about 150 μm (or less).

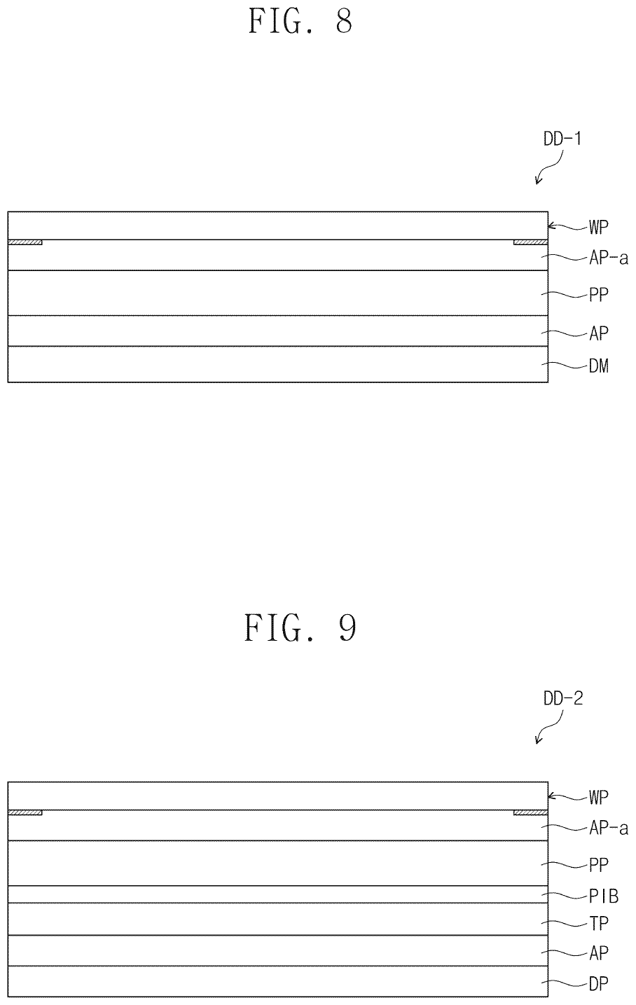

FIG. 8 is a cross-sectional view of a display device according to one or more embodiments. In the description on the display device according to one or more embodiments illustrated in FIG. 8, duplicate contents, previously described with reference to FIGS. 1 to 7, will not be described again, and differences will be mainly described.

Compared to the display device DD described with reference to FIGS. 6 and 7, a display device DD-1 according to the embodiment illustrated in FIG. 8 may further include a light control layer PP and an optical adhesion layer AP-a. The display device DD-1 according to one or more embodiments may further include the light control layer PP arranged between an adhesion member AP and a window WP, and the optical adhesion layer AP-a arranged between the light control layer PP and the window WP.

The light control layer PP may be arranged on a display panel DP, and may control reflected light of external light on the display panel DP. The light control layer PP may include, for example, a polarization layer, or include a color filter layer.

The optical adhesion layer AP-a may be an optically clear adhesive (OCA) film, or an optically clear adhesive resin (OCR) layer. The optical adhesion layer AP-a may be provided from a manufacturing method for an adhesion member according to one or more embodiments, same as that of the adhesion member AP (see FIG. 7) according to the embodiment previously described. A resin composition, which forms the optical adhesion layer AP-a through a polymerization reaction by a photoinitiator, may have a viscosity of at least about 10 mPa·s (or greater) and at most about 30 mPa·s (or less) at at least about 20° C. (or higher) and at most about 30° C. (or lower) if (e.g., when) the viscosity is measured in a JIS K 2283 method.

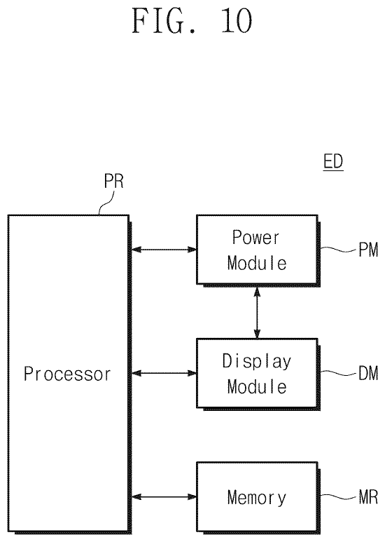

FIG. 9 is a cross-sectional view of a display device according to one or more embodiments. In the description on the display device according to one or more embodiments illustrated in FIG. 9, duplicate contents, previously described with reference to FIGS. 1 to 7, will not be described again, and differences will be mainly described.

Compared to the display device DD described with reference to FIGS. 6 and 7, a display device DD-2 according to the embodiment illustrated in FIG. 9 may further include a light control layer PP, an optical adhesion layer AP-a, and an interlayer adhesion layer PIB. Like the display device DD-1 according to the embodiment illustrated in FIG. 8, the display device DD-2 according to one or more embodiments may further include the light control layer PP arranged between an adhesion member AP and a window WP, and the optical adhesion layer AP-a arranged between the light control layer PP and the window WP.

In the display device DD-2 according to one or more embodiments, the adhesion member AP may be provided between a display panel DP and an input-sensing part TP. For example, the input-sensing part TP may not be directly arranged on the display panel DP, and the display panel DP and the input-sensing part TP may be coupled to each other by the adhesion member AP. For example, the adhesion member AP may be arranged between the encapsulation layer TFE (see FIG. 7) of the display panel DP and the input-sensing part TP.

The interlayer adhesion layer PIB may be provided the light control layer PP. The interlayer adhesion layer PIB may be arranged between the input-sensing part TP and the light control layer PP, and may be made of an adhesive material excellent or suitable in prevention of moisture permeation. For example, the interlayer adhesion layer PIB may include polyisobutylene. The interlayer adhesion layer PIB may be arranged on the input-sensing part TP to prevent or reduce corrosion of sensing electrodes of the input-sensing part TP.

The display device according to one or more embodiments may be applied to one or more suitable electronic devices. An electronic device according to one or more embodiments may include the display device previously described, and in addition to the display device, the electronic device may further include a module or device having another additional function.

The electronic device may include a display device containing an adhesion member AP made of a resin composition, and a control part that controls the display device. The electronic device according to one or more embodiments may be activated in response to electrical signals. The electronic device may include display devices according to one or more suitable embodiments. For example, the electronic device may include a large-size display device including a television, a monitor, and/or an outdoor billboard, and a small- and medium-size display device including a personal computer, a laptop computer, a personal digital assistant, a display device for a vehicle, a game console, a portable electronic device, and/or a camera.

FIG. 10 is a block diagram of an electronic device according to one or more embodiments. Referring to FIG. 10, an electronic device ED according to one or more embodiments may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), and/or a controller.

In the memory MR, data information necessary for operation of the processor PR or the display module DM may be stored. If (e.g., when) the processor PR runs an application stored in the memory MR, movie data signals and/or input control signals may be transmitted to the display module DM, and the display module DM may process the received signals to output movie information through a display screen.

The power module PM may include a power supply module such as a power adapter or a battery device, and a power-converting module that converts power supplied by the power supply module and generate power necessary for operation of the electronic device ED.

At least one selected from among the components of the electronic device ED, previously described, may be included in the display device according to the embodiments previously described. In some embodiments, some of individual modules, included in one functional module, may be included in the display device and others may also be provided separately from the display device. For example, the display device may include the display module DM, and the processor PR, the memory MR, and the power module PM may be provided in the form of a device other than the display device in the electronic device ED.

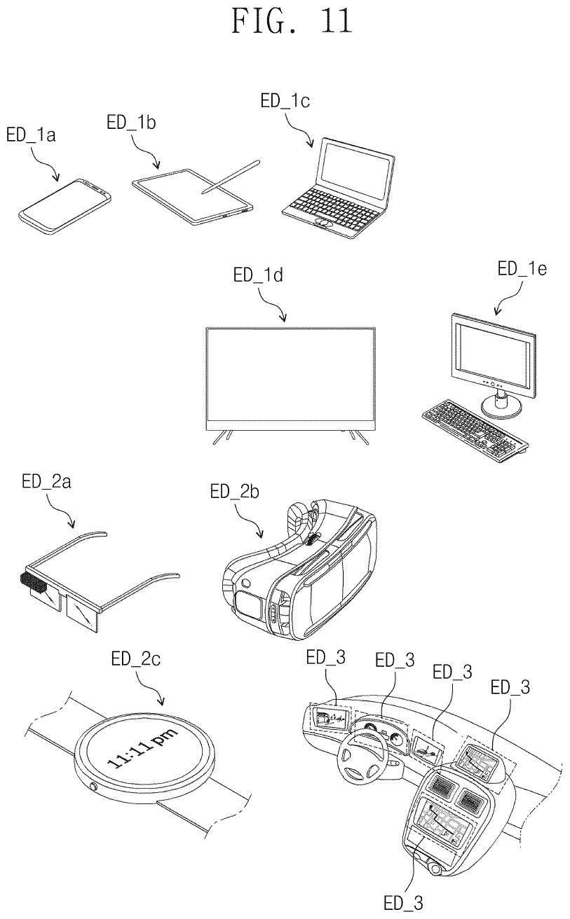

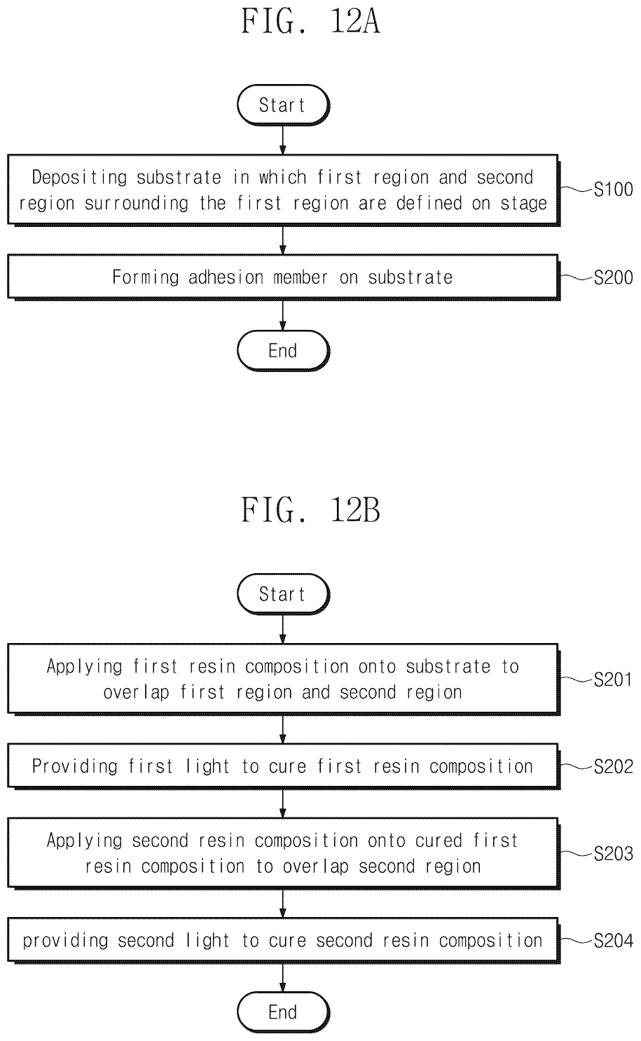

FIG. 11 shows schematic views of an electronic device according to one or more suitable embodiments.

Referring to FIG. 11, one or more suitable electronic devices applied with display devices according to one or more embodiments may not only include electronic devices for displaying images such as a smartphone ED_1a, a tablet PC ED_1b, a laptop computer ED_1c, a TV ED_1d, and a desktop monitor ED_1e, but also include wearable electronic devices containing display modules such as smart glasses ED_2a, a head-mounted display ED_2b, and a smart watch ED_2c, electronic devices for a vehicle ED_3 containing display modules such as a car dashboard, a center fascia, a center information display (CID) arranged on a dashboard, and a room mirror display, and/or the like.

### Method for Manufacturing a Display Device

Hereinafter, a manufacturing method for a display device according to one or more embodiments is described with reference to FIGS. 12A, FIG. 12B, and FIGS. 13A to 13K. In the description on the manufacturing method for the display device according to one or more embodiments, description on the display device according to the embodiment previously described may be applied to the display device. In the description on the manufacturing method for the display device according to one or more embodiments as, duplicate contents previously described on the display device according to the embodiment is not described again, and differences are mainly described.

The manufacturing method for the display device according to one or more embodiments may be the manufacturing method for the display device DD, DD-a, and DD-b according to the embodiment described with reference to FIGS. 1 to 9. In one or more embodiments, a manufacturing method for a display device including an adhesion member AP arranged on a display panel DP of the display device DD, DD-a, and DD-b is provided.

FIG. 12A is a flow chart of a manufacturing method for a display device according to one or more embodiments. FIG. 12B is a flow chart detailing a step (e.g., act or task) of forming an adhesion member in the manufacturing method for the display device according to one or more embodiments. FIGS. 13A to 13K are drawings schematically illustrating a step (e.g., act or task) of forming an adhesion member according to one or more embodiments.

Referring to FIG. 12A, the manufacturing method for the display device according to one or more embodiments includes applying (e.g., depositing) a substrate, in which a first region and a second region around (e.g., surrounding) the first region are defined, on a stage (S100), and forming an adhesion member on the substrate (S200).

Referring to FIG. 12B, the forming of the adhesion member according to one or more embodiments (S200) may include applying a first resin composition onto the substrate to overlap the first region and the second region (S201), providing a first light to cure the first resin composition (S202) and provide a cured first resin composition, applying a second resin composition onto the cured first resin composition to overlap the second region (S203), and providing a second light to cure the second resin composition (S204). In this specification, the applying of the first resin composition (S201) may be referred to as performing a first application, and the applying of the second resin composition (S203) may be referred to as performing a second application. For example, the forming of the adhesion member includes a two-step application process: a first resin composition is applied to overlap both the first and second regions of the substrate and then cured with a first light source (referred to as the first application). Subsequently, a second resin composition is applied over the cured first resin in the second region and cured with a second light source (referred to as the second application).

The manufacturing method for the display device according to one or more embodiments may include the applying (e.g., depositing) of the substrate RP onto the stage ST. The applying (e.g., depositing) of the substrate RP onto the stage ST may include or be preparing the substrate RP for forming an adhesion member AP. Referring to FIG. 13A, the manufacturing method for the display device according to one or more embodiments may include providing the substrate RP on which the adhesion member AP is formed. The substrate RP may provide a base surface on which the adhesion member AP is formed. For example, the substrate RP may be the display panel DP or the window WP described with reference to FIG. 7.

The stage ST may provide a space for the substrate RP to be deposited. The stage ST may be provided in the form of a plate. FIG. 13A illustrates an example where the stage ST has a quadrilateral shape on a plane, but one or more embodiments is not limited thereto, and the shape and size of the stage ST on a plane may be one or more suitable selections.

In the substrate RP, a first region AA1 and a second region AA2 may be defined. The first region AA1 and the second region AA2 may be regions randomly selected or set on the substrate RP for an inkjet printing process to be described in more detail. The first region AA1 may correspond to a central portion of the substrate RP. The second region AA2 may correspond, relatively, to a boundary portion of the substrate RP, compared to the first region AA1. On a plane defined by a first direction DR1 and a second direction DR2, the second region AA2 may be around or surround the first region AA1.

The area of the first region AA1 on a plane may be more than or larger than the area of the second region AA2 on a plane. According to one or more embodiments, the first region AA1 of the substrate RP may correspond to at least a portion of the display region DA of the display device DD (see FIG. 1). In some embodiments, the second region AA2 of the substrate RP may correspond to at least a portion of the non-display region NDA of the display device DD (see FIG. 1).

In one or more embodiments, the second region AA2 may have a width of at most about 3 mm (or less). As illustrated in FIG. 13B, a first width W1 of the second region AA2 in the first direction DR1 and a second width W2 of the second region AA2 in the second direction DR2 may each be at most about 3 mm (or less).

Referring to FIGS. 13B and 13C, the manufacturing method for the display device according to one or more embodiments of the disclosure may further include, before the applying of the first resin composition (S201), forming the substrate RP into a first bitmap, dividing the second region AA2 into at least two (e.g., or more) first unit regions (e.g., SUA1 and SUA2) on the first bitmap, and setting an application amount of the first resin composition RS1 (see FIG. 13D) to be provided to each of the first region AA1 and the first unit regions SUA1 and SUA2. In a case that the manufacturing method for the display device according to one or more embodiments further includes the forming of the substrate RP into the first bitmap, the first region AA1 and the second region AA2 of the substrate RP may be set on the basis of the number of pixels PX included in the first bitmap.

Referring to FIG. 13B, the substrate RP may be formed into the first bitmap including a plurality of pixels PX arranged along a first direction DR1 and a second direction DR2. The substrate RP may be divided into “m” pixels PX arranged along the first direction DR1, and divided into “g” pixels PX arranged along the second direction DR2. Therefore, the substrate RP may be divided into “m×g” pixels PX arranged along the first direction DR1 and the second direction DR2.

Each of the “m” pixels PX arranged along the first direction DR1 may have the same width in the first direction DR1, and each of the “g” pixels PX arranged along the second direction DR2 may have the same width in the second direction DR2, but one or more embodiments is not limited thereto. The length of the substrate RP in the first direction DR1 may be about “m” times the length of the pixel PX in the first direction DR1. The length of the substrate RP in the second direction DR2 may be about “g” times the length of the pixel PX in the second direction DR2.

FIG. 13B illustrates an example where the substrate RP is divided into about 15 pixels PX in the first direction DR1, and divided into about 23 pixels PX in the second direction DR2, but one or more embodiments is not limited thereto. For example, the number of pixels PX and the lengths of the pixels PX in the first direction DR1 and the second direction DR2 selected or set for forming the substrate RP into the first bitmap may be appropriately or suitably adjusted according to a process condition, resolution for an inkjet printing instrument, and/or the like.

After the substrate RP is formed into the first bitmap including the “m×g” pixels PX, the dividing of the second region AA2 into at least two (e.g., two or or more) first unit regions (e.g., SUA1 and SUA2) may be performed. For example, the second region AA2 may be divided into a plurality of first unit regions SUA1 and SUA2, each plurality of first unit regions having a different application amount of the first resin composition RS1 (see FIG. 13D). The plurality of first unit regions SUA1 and SUA2 may each be arranged on the boundary of the substrate RP, and may each have a shape around (e.g., surrounding) the first region AA1 on a plane.

After the dividing of the second region AA2 into the plurality of first unit regions SUA1 and SUA2 on the first bitmap, the setting of the application amounts of the first resin composition RS1 (see FIG. 13D) for the first region AA1 and the plurality of first unit regions SUA1 and SUA2 may be performed. The application amount for each region may be set such that the application amount of the first resin composition RS1 (see FIG. 13D) to be applied to the plurality of first unit regions SUA1 and SUA2 is less or smaller than the application amount of the first resin composition RS1 (see FIG. 13D) to be applied to the first region AA1. Here, the application amount of the first resin composition RS1 (see FIG. 13D) to be applied to the plurality of first unit regions SUA1 and SUA2 refers to the average value of the application amount of the first resin composition RS1 to be applied to each (e.g., first unit) of the plurality of first unit regions SUA1 and SUA2.

As shown in Table 1, on the first bitmap, the second region AA2 may be divided into at least two (e.g., two or more) first unit regions SUA1, . . . , and SUAn, and the application amount of the first resin composition RS1 (see FIG. 13D) may be set for each (e.g., first unit) of the plurality of first unit regions SUA1, . . . , and SUAn. Accordingly, the application amount of the plurality of first unit regions SUA1, . . . , and SUAn refers to a comparative amount for each (e.g., first unit) of the plurality of first unit regions SUA1, . . . , and SUAn when the application amount for the first region AA1 is 100.

TABLE 1

| | | | |
|---|---|---|---|
| First unit region | SUA1 | . . . | SUAn |
| Application amount | X1 | . . . | Xn |
| Number of pixels (units) | A1 | . . . | An |

Referring to Table 1, the second region AA2 may be divided into n first unit regions SUA1, . . . , and SUAn. In Table 1, n may be an integer of 2 or greater. In this specification, the phrase “1st first unit region to the n-th first unit region (SUA1, . . . , and SUAn)” may be referred to as the phrase “a (1-1)-th unit region to a (1-n)-th unit region,” respectively. For example, when n is 2, the “1st first unit region SUA1” may refer to the “(1-1)-th unit region,” and the “2nd first unit region SUA2” may refer to the “(1-2)-th unit region.” Referring to FIG. 13B and Table 1 together, n first unit regions SUA1, . . . , and SUAn may be sequentially arranged in one direction toward an edge portion of the substrate RP from the first region AA1. For example, as illustrated in FIG. 13B, when n is 2, the (1-1)-th unit region SUA1 and the (1-2)-th unit region SUA2 may be sequentially arranged in the one direction toward the edge portion of the substrate RP from the first region AA1. In one or more embodiments, when n is 3, the (1-1)-th unit region SUA1, the (1-2)-th unit region SUA2, and a (1-3)-th unit region SUA3 may be sequentially arranged in the one direction toward the edge portion of the substrate RP from the first region AA1. The n first unit regions SUA1, . . . , and SUAn may each have a closed line shape around (e.g., surrounding) the first region AA1 on a plane.

The n first unit regions SUA1, . . . , and SUAn may each include a set or predetermined number of pixels PX. In Table 1, A1, . . . , and An may refer to the number of pixels PX included in the 1st first unit region to the n-th first unit region SUA1, . . . , and SUAn, respectively.

Application amounts X1, . . . , and Xn of the first resin composition RS1 (see FIG. 13D) may be set respectively for the n first unit regions SUA1, . . . , and SUAn. At least one selected from among the application amounts X1, . . . , and Xn for the n first unit regions SUA1, . . . , and SUAn may have a different value. In a case that the second region AA2 includes two first unit regions (e.g., SUA1 and SUA2), the application amount X1 of the (1-1)-th unit region SUA1 corresponding to the 1st first unit region and the application amount X2 of the (1-2)-th unit region SUA2 corresponding to the 2nd first unit region may be different from each other. In one or more embodiments, in a case that the second region AA2 includes three first unit regions, at least one of the application amount X1 of the (1-1)-th unit region SUA1 corresponding to the 1st first unit region, the application amount X2 of the (1-2)-th unit region SUA2 corresponding to the 2nd first unit region, or an application amount X3 of the (1-3)-th unit region SUA3 corresponding to the 3rd first unit region may have a different value. For example, the application amount X1 of the (1-1)-th unit region SUA1, the application amount X2 of the (1-2)-th unit region SUA2, and the application amount X3 of the (1-3)-th unit region SUA3 may each be different from each other.

In one or more embodiments, when the application amount of the first resin composition for the first region AA1 is 100, the average application amount of the first resin composition RS1 (see FIG. 13D) for the plurality of first unit regions SUA1 and SUA2 may be less or smaller than the application amount of the first resin composition RS1 (see FIG. 13D) for the first region AA1. For example, when the application amount of the first resin composition RS1 (see FIG. 13D) for the first region AA1 is 100, the average application amount of the first resin composition RS1 (see FIG. 13D) for the n first unit regions SUA1, . . . , and SUAn may be less or smaller than the application amount of the first resin composition RS1 (see FIG. 13D) for the first region AA1. The average application amount of the first resin composition RS1 (see FIG. 13D) for the plurality of first unit regions SUA1 and SUA2 may be calculated by Expression 1. In one or more embodiments, an average application amount of the first resin composition RS1 for the plurality of first unit regions SUA1 and SUA2, may be calculated by Expression 1, and may be at least about 50 (or greater) and at most about 85 (or less).

$$[ ( X 1 \times A 1 ) + … ( Xn \times An ) ] \div ( A 1 + … An ) \qquad Expression 1$$

In Expression 1, X1 to Xn (e.g., X1, X2, . . . Xn) are independently application amounts of the first resin composition RS1 (see FIG. 13D) respectively for the 1st first unit region SUA1 to the n-th first unit region SUAn (e.g., SUA1, SUA2, . . . , and SUAn) when the application amount of the first resin composition RS1 (see FIG. 13D) to be applied to the first region AA1 is 100. For example, the application amount of the first resin composition RS1 (see FIG. 13D) for each of the 1st first unit region to the n-th first unit region (SUA1, . . . , and SUAn) may refer to a comparative value when the application amount of the first resin composition RS1 (see FIG. 13D) to be applied to the first region AA1 is 100.

In Expression 1, A1 to An (e.g., A1, A2, . . . . An) may independently refer to the number of pixels PX in the 1st first unit region to the n-th first unit region SUA1, . . . , and SUAn, respectively.

In Expression 1, n is an integer of 2 or greater. For example, n may be an integer of 2 or greater and 4 or less.

Hereinafter, referring to FIGS. 13B and 13C, the manufacturing method for the display device according to one or more embodiments, may include the dividing of the second region AA2 into two first unit regions SUA1 and SUA2 and the setting of the application amount of the first resin composition RS1 (see FIG. 13D) for each of the two first unit regions SUA1 and SUA2, is described in more detail. FIGS. 13B and 13C illustrate an example where the second region AA2 is divided into two first unit regions SUA1 and SUA2, but one or more embodiments is not limited thereto, and the second region AA2 may also be divided into three or more first unit regions as previously described.

As illustrated in FIG. 13B, the second region AA2 may be divided into the two first unit regions SUA1 and SUA2. For example, the second region AA2 may be divided into the (1-1)-th unit region SUA1 and the (1-2)-th unit region SUA2. The (1-1)-th unit region SUA1 may be adjacent to the first region AA1. On a plane, the (1-1)-th unit region SUA1 may surround the first region AA1. The (1-2)-th unit region SUA2 may be spaced and/or apart (e.g., spaced apart or separated) from the first region AA1 with the (1-1)-th unit region SUA1 therebetween. On a plane, the (1-2)-th unit region SUA2 may surround the (1-1)-th unit region SUA1.

In one or more embodiments, the first unit regions SUA1 and SUA2 may each be distinguished by pixel distance. The “pixel distance” may refer to the number of pixels PX included in a width distance of each of the unit regions. The width of each of the unit regions may refer to a width in the first direction DR1 and a width in the second direction DR2. In each of the unit regions, the number of pixels PX included in the width distance in the first direction DR1 and the number of pixels PX included in the width distance in the second direction DR2 may be equal to each other. For example, the (1-1)-th unit region SUA1 illustrated in FIG. 13B may include one pixel PX in the width distance each in the first and second directions DR1 and DR2, and in this case, the pixel distance of the (1-1)-th unit region SUA1 may be 1. In some embodiments, the (1-2)-th unit region SUA2 illustrated in FIG. 13B may include one pixel PX in the width distance each in the first and second directions DR1 and DR2, and in this case, the pixel distance of the (1-2)-th unit region SUA2 may be 1.

FIG. 13C is a graph randomly showing the setting of the application amount of the first resin composition RS1 (see FIG. 13D) to be applied to each of the first region AA1 and the two first unit regions SUA1 and SUA2 of the substrate RP illustrated in FIG. 13B. In the graph of FIG. 13C, the vertical axis refers to the application amount. In the graph of FIG. 13C, “X1” is an application amount of the first resin composition RS1 (see FIG. 13D) to be applied to the (1-1)-th unit region SUA1, “X2” is an application amount of the first resin composition RS1 (see FIG. 13D) to be applied to the (1-2)-th unit region SUA2, and “Z” is an application amount of the first resin composition RS1 (see FIG. 13D) to be applied to the first region AA1. The application amount of the first resin composition RS1 (see FIG. 13D) to be applied to each of the (1-1)-th and (1-2)-th unit regions SUA1 and SUA2 may refer to a comparative value if (e.g., when) the application amount of the first resin composition RS1 (see FIG. 13D) to be applied to the first region AA1 is 100.

Referring to FIG. 13C, the application amount Z of the first resin composition RS1 (see FIG. 13D) to be applied to the first region AA1 may be constant. If (e.g., when) the application amount Z of the first resin composition RS1 (see FIG. 13D) to be applied to the first region AA1 is 100, the application amount for each of the first unit regions SUA1 and SUA2 may be set. For example, the application amount of the first resin composition RS1 (see FIG. 13D) to be applied to the (1-1)-th unit region SUA1 and the application amount of the first resin composition RS1 (see FIG. 13D) to be applied to the (1-2)-th unit region SUA2 may each be set. The average application amount of the first resin composition RS1 (see FIG. 13D) to be applied to the two first unit regions SUA1 and SUA2 may be smaller than the application amount of the first resin composition RS1 (see FIG. 13D) to be applied to the first regions AA1. Here, the average application amount may be calculated by Expression 1 previously described.

FIGS. 13D and 13E are drawings illustrating the applying of the first resin composition RS1 onto the substrate RP (S201) in the forming of the adhesion member according to one or more embodiments of the disclosure. FIG. 13E is a cross-sectional view of a portion corresponding to line II-II′ of FIG. 13D.

For example, in one or more embodiments, prior to applying the first resin composition, the substrate is converted into a bitmap composed of pixels arranged along two orthogonal directions (e.g., DR1 and DR2). The second region surrounding the first region is divided into n first unit regions (SUA1 to SUAn), each containing a defined number of pixels and arranged sequentially from the first region toward the edge of the substrate. These unit regions may form concentric or surrounding shapes around the first region in plan view. Each unit region is assigned a specific application amount of the first resin composition, which may differ from one another and is typically less than the amount applied to the first region. The application amounts (X1 to Xn) and pixel counts (A1 to An) for each unit region are used to calculate an average application amount using the following weighted formula:

$$[ ( X 1 \times A 1 ) + … ( Xn \times An ) ] \div ( A 1 + … An ) \qquad Expression 1$$

This average is generally between 50 and 85 when the application amount for the first region is set to 100. For example, when the second region is divided into two unit regions—(1-1)-th unit region (SUA1) adjacent to and surrounding the first region, and (1-2)-th unit region (SUA2) surrounding SUA1—the application amounts X1 and X2 may be set differently, and their average will be less than the application amount Z applied to the first region. The unit regions may also be defined by pixel distance, referring to the number of pixels in their width along both directions. This bitmap-based approach enables precise control of resin distribution, as illustrated in FIGS. 13B-13E and Table 1, enhancing the adhesion profile for the display device.

Referring to FIGS. 13D and 13E, the applying of the first resin composition RS1 onto the substrate RP may be performed to overlap the first region AA1 and the second region AA2. The first resin composition RS1 may be provided onto the substrate RP through inkjet printing. The first resin composition RS1 may be discharged from a first inkjet head IHD1 and provided onto the substrate RP.

The first inkjet head IHD1 may be arranged on an upper part of a stage ST. The first inkjet head IHD1 may be arranged at a set or predetermined distance apart from an upper surface of the stage ST such that the discharging process, in which the first resin composition RS1 is discharged from the first inkjet head IHD1 onto the substrate RP, may be performed.

The first inkjet head IHD1 may include a plurality of first nozzles NZ1. The plurality of first nozzles NZ1 may be arranged apart from each other at regular intervals along one direction. The plurality of first nozzles NZ1 may be arranged in a row. However, one or more embodiments is not limited thereto, and the plurality of first nozzles NZ1 may also be arranged in two or more rows. The plurality of first nozzles NZ1 may each discharge the first resin composition RS1 described herein and/or ink(s) toward the substrate RP. For example, a discharging direction of each of the plurality of first nozzles NZ1 may be a direction perpendicular to the substrate RP. However, one or more embodiments is not limited thereto.

The plurality of first nozzles NZ1 may each include an outlet having a shape of a circular hole. However, one or more embodiments is not limited thereto, and the shape of the outlet of each of the plurality of first nozzles NZ1 may vary. In some embodiments, the number and size of the plurality of first nozzles NZ1 included in the first inkjet head IHD1 may vary.

The plurality of first nozzles NZ1 included in the first inkjet head IHD1 may be controlled or selected independently by a control component or part. Through the control component or part, discharge of the first resin composition RS1 by each of the first nozzles NZ1 is controlled or selected, so that it is possible to apply the first resin composition RS1 and/or ink(s) onto the substrate RP in a desired or suitable shape. In some embodiments, the first inkjet head IHD1 may further include a storage component or part that stores the first resin composition RS1 to be discharged to the substrate RP.

Referring to FIGS. 13B to 13E together, the applying of the first resin composition RS1 may be applying the first resin composition RS1 onto the first region AA1 and the second region AA2 according to the set application amount. In the applying of the first resin composition RS1, the first inkjet head IHD1 may discharge the first resin composition RS1 onto the first region AA1 and the second region AA2 while moving in the second direction DR2. However, one or more embodiments is not limited thereto, and the first inkjet head IHD1 may also discharge the first resin composition RS1 while moving in the first direction DR1.

By controlling the application amount of the first resin composition RS1 sprayed from the plurality of first nozzles NZ1 of the first inkjet head IHD1, the first resin composition RS1 may be applied onto the first region AA1 of the substrate RP in a first application amount, and the first resin composition RS1 may be applied onto the second region AA2 of the substrate RP in a second application amount. In one or more embodiments, the second application amount may be less than or smaller than the first application amount.

In a case that the second region AA2 is divided into two or more first unit regions SUA1 and SUA2, the first resin composition RS1 may be applied according to the set application amount for each of the first unit regions SUA1 and SUA2. For example, the second region AA2 may be divided into the (1-1)-th unit region SUA1 and the (1-2)-th unit region SUA2, the first resin composition RS1 may be applied onto the (1-1)-th unit region SUA1 in a (1-1)-th unit application amount, and the first resin composition RS1 may be applied onto the (1-2)-th unit region SUA2 in a (1-2)-th unit application amount. In one or more embodiments, the (1-1)-th unit application amount may be less than or smaller than the (1-2)-th unit application amount. However, one or more embodiments is not limited thereto.

The first resin composition RS1 may have a viscosity of at least about 10 millipascal second (mPa·s) (or greater) and at most about 30 mPa·s (or less) at at least about 20° C. (or higher) and at most about 30° C. (or lower). For example, the first resin composition RS1 may have a viscosity of at least about 10 mPa·s (or greater) and at most about 30 mPa·s (or less) at about 25° C. The viscosity of the first resin composition RS1 may be measured in a JIS K 2283 method.

If (e.g., when) the viscosity of the first resin composition RS1 is less than about 10 mPa·s at a temperature in the range of about 20° C. or higher and about 30° C. or lower, the viscosity may be low, causing a flow of a resin composition liquid provided for forming an adhesion member, and accordingly, it may be difficult to form a coating film having a substantially uniform thickness using the first resin composition RS1. In some embodiments, if (e.g., when) the viscosity of the first resin composition RS1 according to one or more embodiments is greater than about 30 mPa·s at a temperature in the range of about 20° C. or higher and about 30° C. or lower, it may be difficult to discharge the first resin composition RS1 in an appropriate or suitable amount from an application device used for applying the first resin composition RS1.

The first resin composition RS1 may further include at least one photoinitiator. In a case of including a plurality of photoinitiators, the photoinitiators, different from each other, may be activated by UV light, each in a different central wavelength range(s).

The photoinitiator may be any one selected from among 2,2-dimethoxy-1,2-diphenylethan-1-one, 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, and 2-hydroxy-1-{4-[4-(2-hydroxy-2-methyl-propionyl)-benzyl]-phenyl}-2-methylpropan-1-one.

In some embodiments, the photoinitiator may be any one selected from among 2-methyl-1[4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, 2,4,6-trimethylbenzoyl-diphenyl phosphinate, bis(2,4,6-trimethylbenzoyl)-phenylphosphineoxide, [1-(4-phenylsulfanylbenzoyl)heptylideneamino]benzoate, [1-[9-ethyl-6-(2-methylbenzoyl)carbazol-3-yl]ethylideneamino]acetate, and Bis(2,4-cyclopentadienyl)bis[2,6-difluoro-3-(1-pyrryl)phenyl] titanium (IV). The resin composition according to one or more embodiments may include at least any one of Omnirad TPO-H (IGM Resins), Omnirad819 (IGM Resins), or Esacure 3644 (IGM Resins) as the photoinitiator.

The first resin composition RS1 may further include an additive as needed. A general additive suitable to the relevant art may be appropriately or suitably selected as the additive in order to control the property desired or required for an adhesion composition. Examples may include a photostabilizer, a cross-linking agent, an antioxidant, a chain transfer agent, a photosensitizer, a polymerization inhibitor, a leveling agent, a surfactant, an adhesion agent, a plasticizer, a UV absorber, a storage stabilizer, antistatic agent, an inorganic filler, pigment, dye, and/or the like, but the present disclosure is not limited thereto. The additive may be used alone, or may be used as a mixture of two or more thereof.

FIG. 13F is a drawing illustrating curing the first resin composition RS1 in the forming of the adhesion member according to one or more embodiments of the disclosure. FIG. 13F is a cross-sectional view of a portion corresponding to line II-II′ of FIG. 13D.

Referring to FIG. 13F, after the applying of the first resin composition RS1 onto the substrate RP, the curing of the first resin composition RS1 may be performed. A first light L1 may be emitted to the first resin composition RS1 provided onto the substrate RP in liquid. The first light L1 may be UV light, but the present disclosure is not limited thereto. Because the first light L1 is provided to the first resin composition RS1, the first resin composition RS1 may be cured. In this specification, the first resin composition RS1 cured by the first light L1 may be referred to as a preliminary adhesion member P-AP (see FIG. 13G). For example, the first resin composition RS1 may be polymerized and then cured by the provided first light L1 to form the preliminary adhesion member P-AP (see FIG. 13G).

In the curing of the first resin composition RS1, an amount of the first light L1 emitted to the first resin composition RS1 may be an amount of light that is enough to completely cure the first resin composition RS1. However, one or more embodiments is not limited thereto, and in the curing of the first resin composition RS1, polymerization reaction of the first resin composition RS1 may be partially carried out, and then unreacted first resin composition RS1 may be subject to additional reaction in a step (e.g., act or task) of curing a second resin composition RS2, thereby forming a final adhesion member AP (see FIG. 13J).

The preliminary adhesion member P-AP (see FIG. 13G), formed by the curing of the first resin composition RS1, may have different thicknesses in the first region AA1 and the second region AA2. The first application amount of the first resin composition RS1 provided to the first region AA1 may be larger than the second application amount of the first resin composition RS1 provided to the second region AA2. Therefore, the average thickness of the preliminary adhesion member P-AP overlapping the first region AA1 may be larger than the average thickness of the preliminary adhesion member P-AP overlapping the second region AA2.

The first resin composition RS1 may be provided in a substantially uniform application amount onto the first region AA1. Therefore, the preliminary adhesion member P-AP overlapping the first region AA1 may have a substantially uniform thickness. If (e.g., when) the preliminary adhesion member P-AP overlapping the first region AA1 is referred to as a first preliminary adhesion portion, and the preliminary adhesion member P-AP overlapping the second region AA2 is referred to as a second preliminary adhesion portion, the thickness deviation in the second preliminary adhesion portion may be greater than the thickness deviation in the first preliminary adhesion portion. The second region AA2 may be divided into a plurality of first unit regions SUA1 and SUA2, and the first resin composition RS1 may be applied in an application amount set for each of the plurality of first unit regions SUA1 and SUA2. Because the application amount for at least one of the plurality of first unit regions SUA1 or SUA2 is different from the application amount for the other first unit region, the weight deviation in the provided liquid composition may be caused. Therefore, the thickness deviation in the second region AA2 may be greater than the thickness deviation in the first region AA1.

FIGS. 13G and 13H are drawings illustrating the applying of the second resin composition RS2 (S203) in the forming of the adhesion member according to one or more embodiments of the disclosure. FIG. 13H is a cross-sectional view of a portion corresponding to line III-III′ of FIG. 13G.

The second resin composition RS2 may be provided onto the substrate RP through inkjet printing. The second resin composition RS2 may be discharged from a second inkjet head IHD2 and provided onto the substrate RP.

The second inkjet head IHD2 may be arranged on an upper part of a stage ST. The second inkjet head IHD2 may be arranged at a set or predetermined distance apart from an upper surface of the stage ST such that a discharging process, in which the second resin composition RS2 is discharged from the second inkjet head IHD2 onto the preliminary adhesion member P-AP, may be performed.

The second inkjet head IHD2 may include a plurality of second nozzles NZ2. The plurality of second nozzles NZ2 may be arranged apart from each other at regular intervals along one direction. The plurality of second nozzles NZ2 may be arranged in a row. However, one or more embodiments is not limited thereto, and the plurality of second nozzles NZ2 may also be arranged in about two or more rows. The plurality of second nozzles NZ2 may each discharge inks toward the substrate RP. For example, a discharging direction of each of the plurality of second nozzles NZ2 may be a direction perpendicular to the substrate RP. However, one or more embodiments is not limited thereto.

The plurality of second nozzles NZ2 may each include an outlet having a shape of a circular hole. However, one or more embodiments is not limited thereto, and the shape of the outlet of each of the plurality of second nozzles NZ2 may vary. In some embodiments, the number and size of each of the plurality of second nozzles NZ2, included in the second inkjet head IHD2, may vary.

The plurality of second nozzles NZ2 included in the second inkjet head IHD2 may be controlled or selected independently by a control component or part. Through the control component or part, discharge of the second resin composition RS2 by each of the second nozzles NZ2 is controlled or selected, so that it is possible to apply inks onto the substrate the first resin composition RP in a desired or suitable shape. In some embodiments, although not illustrated in the drawing, the second inkjet head IHD2 may further include a storage component or part that stores the second resin composition RS2 to be discharged to the substrate RP.

Referring to FIGS. 13G and 13H, the applying of the second resin composition RS2 onto the preliminary adhesion member P-AP may be performed to overlap the second region AA2 of the substrate RP. The second resin composition RS2 may be applied onto the preliminary adhesion member P-AP to overlap the second region AA2 of the substrate RP. In the applying of the second resin composition RS2, the second resin composition RS2 may be applied only to the second region AA2, and may not be applied to the first region AA1.

In the applying of the second resin composition RS2, the second resin composition RS2 may be applied onto the second region AA2 in a third application amount. The third application amount may be appropriately or suitably set in consideration of a desired or suitable thickness of the preliminary adhesion member P-AP. In one or more embodiments, the third application amount may be smaller than the first application amount, previously described. For example, if (e.g., when) the application amount of the first resin composition RS1 to be applied to the first region AA1 is 100 in the applying of the first resin composition RS1, the application amount of the second resin composition RS2 to be applied to the second region AA2 may be less than about 100 in the applying of the second resin composition RS2.

As the second inkjet head IHD2 moves along the second direction DR2 on the substrate RP, the second resin composition RS2 may be applied onto the second region AA2. If (e.g., when) the second inkjet head IHD2 faces the first region AA1 and the second region AA2 as it moves along the second direction DR2, the second resin composition RS2 may be applied onto the second region AA2 in accordance with the previously set application amount. By applying the second resin composition RS2 onto the second region AA2, the thickness deviation in the preliminary adhesion member P-AP may be reduced.

The second resin composition RS2 may have a viscosity of at least about 10 mPa·s (or greater) and at most about 30 mPa·s (or less) at at least about 20° C. (or higher) and at most about 30° C. (or lower). For example, the second resin composition RS2 may have a viscosity of about 10 mPa·s or greater and about 30 mPa·s or less at about 25° C. The viscosity of the second resin composition RS2 may be measured in a JIS K 2283 method.

If (e.g., when) the viscosity of the second resin composition RS2 is less than about 10 mPa·s at a temperature in the range of about 20° C. or higher and about 30° C. or lower, the viscosity may be low, causing a flow of a resin composition liquid provided for forming an adhesion member, and accordingly, it may be difficult to form a coating film having a substantially uniform thickness using the second resin composition RS2. In some embodiments, if (e.g., when) the viscosity of the second resin composition RS2 according to one or more embodiments is greater than about 30 mPa·s at a temperature in the range of about 20° C. or higher and about 30° C. or lower, it may be difficult to discharge the second resin composition RS2 in an appropriate or suitable amount from an application device used for applying the second resin composition RS2.

The second resin composition RS2 may further include at least one photoinitiator. In case of including a plurality of photoinitiators, the photoinitiators, different from each other, may be activated by UV light each in a different central wavelength range(s). The content (e.g., amount) previously described for the first resin composition RS1 may be equally applied to the photoinitiator. In some embodiments, the second resin composition RS2 may further include an additive as needed. The content (e.g., amount) previously described for the first resin composition RS1 may be equally applied to the additive.

In one or more embodiments, the first resin composition RS1 and the second resin composition RS2 may be the same. In some embodiments, the first inkjet head IHD1 that discharges the first resin composition RS1 and the second inkjet head IHD2 that discharges the second resin composition RS2 may be the same. However, one or more embodiments is not limited thereto.

FIGS. 13I and 13J are drawings illustrating curing a second resin composition RS2 to form an adhesion member AP in the forming of the adhesion member (S204) according to one or more embodiments of the disclosure. FIG. 13K is a cross-sectional view of a portion corresponding to line IV-IV′ of FIG. 13J.

Referring to FIGS. 13I and 13J, after the applying of the second resin composition RS2, the curing of the second resin composition RS2 may be performed. A second light L2 may be emitted to the second resin composition RS2 provided onto the substrate RP. The second light L2 may be UV light, but the present disclosure is not limited thereto. Because the second light L2 is provided to the second resin composition RS2, the second resin composition RS2 may be cured. The second resin composition RS2 may be polymerized and then cured by the provided second light L2 to form the adhesion member AP (see FIG. 13J) with the preliminary adhesion member P-AP. FIG. 13I illustrates an example where the second light L2 is emitted both (e.g., simultaneously) to the first region AA1 and the second region AA2, but one or more embodiments is not limited thereto, and the second light L2 may be selectively emitted only to the second region AA2 according to the degree of curing of the preliminary adhesion member P-AP.

Referring to FIGS. 13J and 13K, the adhesion member AP may include a first adhesion portion overlapping the first region AA1, and a second adhesion portion overlapping the second region AA2. The adhesion member AP may have a flat upper surface on the first adhesion portion. The adhesion member AP may have a peak part PK at which a thickness in the third direction DR3 becomes maximum toward an edge of the adhesion member AP in the second adhesion portion. The peak part PK may refer to a portion which overlaps the second region AA2, and a portion having a maximum height hm from a lower surface AP-LF of the adhesion member AP adjacent to the substrate RP to an upper surface AP-UF of the adhesion member AP spaced and/or apart (e.g., spaced apart or separated) from the substrate RP. In the adhesion member AP according to one or more embodiments, the thickness of the adhesion member AP in the third direction DR3 may decrease gradually toward the edge from the peak part PK. In this specification, a portion of the second adhesion portion where the thickness decreases toward the edge from the peak part PK may be referred to as a slope.

A horizontal distance dₚ from the edge of the adhesion member AP to the peak part PK may be about 600 μm or less. For example, the horizontal distance dₚ from the edge of the adhesion member AP to the peak part PK may be at least about 300 micrometer (μm) (or greater) and at most about 600 μm (or less). The horizontal distance dₚ from the edge to the peak part PK may refer to the shortest distance measured between a first virtual line LN extending from the peak part PK in the third direction DR3 to the edge of the adhesion member AP. If (e.g., when) the horizontal distance dₚ from the edge of the adhesion member AP to the peak part PK increases, the slope may be visible from the outside of the display device DD, DD-a, and DD-b (see FIGS. 1, 3, and 5), thereby deteriorating the movie quality.

According to one or more embodiments of the disclosure, in a process of applying the resin composition through inkjet printing, two cycles of application processes are introduced, and the application amount of the resin composition, provided according to the region, is controlled or selected, thereby exhibiting effect of reducing the length of the slope formed on the adhesion member, which is the horizontal distance dₚ from the edge of the adhesion member AP to the peak part PK, to a certain range.

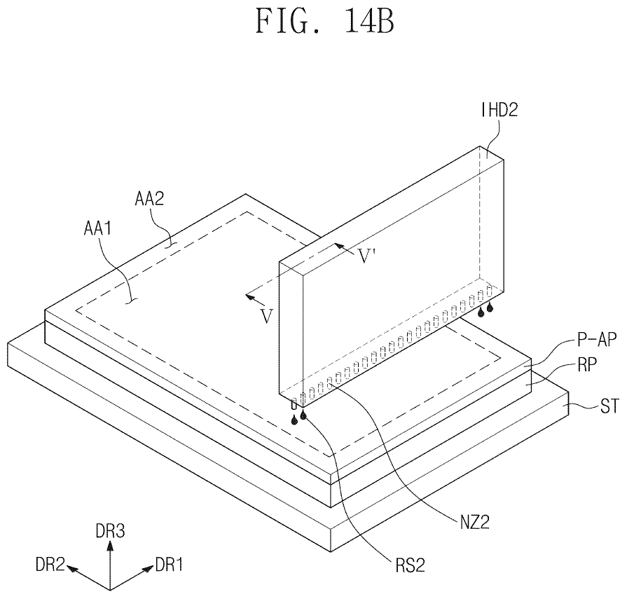

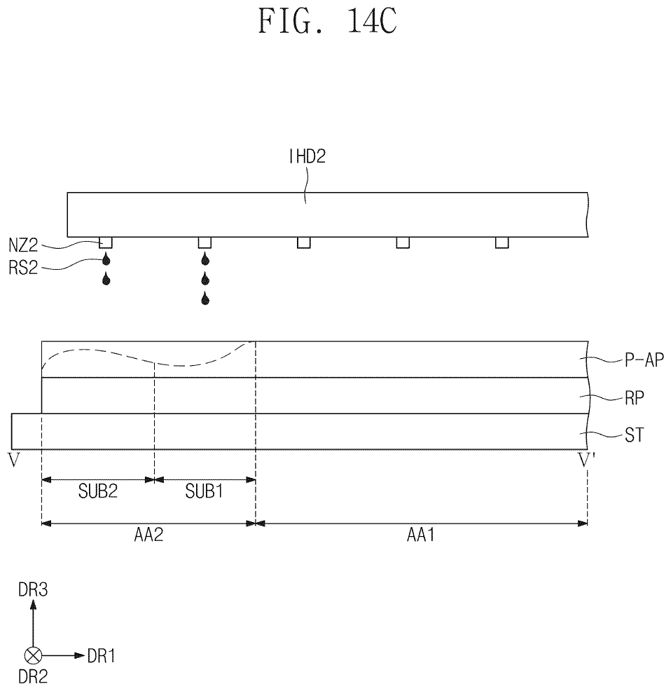

FIGS. 14A to 14C are drawings illustrating some steps of a manufacturing method for a display device according to one or more embodiments of the disclosure. FIGS. 14A to 14C are drawings schematically illustrating a step (e.g., act or task) of forming an adhesion member according to one or more embodiments of the disclosure. Hereinafter, in describing a manufacturing method for a display device, according to one or more embodiments of the disclosure, with reference to FIGS. 14A to 14C, the same reference numerals or symbols are given to components that are substantially identical to those previously described, and detailed description thereof is not provided.

The manufacturing method for the display device illustrated in FIGS. 14A to 14C is different from the manufacturing method for the display device described with reference to FIGS. 13A to 13K in the way of applying a second resin composition RS2 onto the second region AA2 in applying the second resin composition RS2.

Referring to FIGS. 14A to 14C, before applying the second resin composition RS2 onto a preliminary adhesion member P-AP, forming a substrate RP into a second bitmap, dividing the second region AA2 into two or more second unit regions SUB1 and SUB2 on the second bitmap, and setting application amounts for the second unit regions SUB1 and SUB2 may be further included. In case that the manufacturing method for the display device according to one or more embodiments further includes the forming of the substrate RP into the second bitmap, the first region AA1 and the second region AA2 of the substrate RP may be reset on the basis of the number of pixels PX included in the second bitmap.

Referring to FIG. 14A, the substrate RP may be formed into the second bitmap including a plurality of pixels PX arranged along a first direction DR1 and a second direction DR2. In the forming of the second bitmap, the substrate RP may be divided into “p” pixels PX arranged along the first direction DR1, and divided into “q” pixels PX arranged along the second direction DR2. Therefore, the substrate RP may be divided into “p×q” pixels PX arranged along the first direction DR1 and the second direction DR2. “p” and “q” in FIG. 14A may be respectively equal to “m” and “g” previously described with reference to FIG. 13B. For example, the number of entire pixels PX on the second bitmap may be equal to the number of entire pixels PX on the first bitmap previously described. However, one or more embodiments is not limited thereto.

The “p” pixels PX arranged along the first direction DR1 may have the same width in the first direction DR1, and the “q” pixels PX arranged along the second direction DR2 may have the same width in the second direction DR2, but one or more embodiments is not limited thereto. The length of the substrate RP in the first direction DR1 may be about p times the length of the pixel PX in the first direction DR1. The length of the substrate RP in the second direction DR2 may be about q times the length of the pixel PX in the second direction DR2.

FIG. 14A illustrates that, in the forming of the second bitmap, the substrate RP is divided into about 15 pixels PX in the first direction DR1 and divided into about 23 pixels PX in the second direction DR2, but one or more embodiments is not limited thereto. The number of pixels PX and the length of the pixel PX each in the first direction DR1 and the second direction DR2, set for forming the substrate RP into the second bitmap, may be appropriately or suitably adjusted according to a process condition, resolution for an inkjet printing instrument, and/or the like.

After the substrate RP is formed into the second bitmap including the “p×q” pixels PX, the dividing of the second region AA2 into two or more second unit regions SUB1 and SUB2 may be performed. The second region AA2 may be divided into a plurality of second unit regions SUB1 and SUB2 having different application amounts of the second resin composition RS2. The plurality of second unit regions SUB1 and SUB2 may each be arranged on a boundary of the substrate RP, and may each have a shape around (e.g., surrounding) the first region AA1 on a plane. The plurality of second unit regions SUB1 to SUB2 may each have a closed line shape around (e.g., surrounding) the first region AA1 on a plane.

As illustrated in FIG. 14A, the second region AA2 may be divided into a (2-1)-th unit region SUB1 and a (2-2)-th unit region SUB2. The (2-1)-th unit region SUB1 may be adjacent to the first region AA1. On a plane, the (2-1)-th unit region SUB1 may surround the first region AA1. The (2-2)-th unit region SUB2 may be spaced and/or apart (e.g., spaced apart or separated) from the first region AA1 with the (2-1)-th unit region SUB1 therebetween. On a plane, the (2-2)-th unit region SUB2 may surround the (2-1)-th unit region SUB1. FIG. 14A illustrates an example where the second region AA2 is divided into two second unit regions SUB1 and SUB2, but one or more embodiments is not limited thereto, and the second region AA2 may also be divided into three or more second unit regions.

In one or more embodiments, the second unit regions SUB1 and SUB2 may each be distinguished by pixel distance. The “pixel distance” may refer to the number of pixels PX included in a width distance of each of the unit regions. The width of each of the unit regions may refer to a width in the first direction DR1 and a width in the second direction DR2. In each of the unit regions, the number of pixels PX included in the width distance in the first direction DR1 and the number of pixels PX included in the width distance in the second direction DR2 may be equal to each other. For example, the (2-1)-th unit region SUB1 illustrated in FIG. 14A may include one pixel PX in the width distance each in the first and second directions DR1 and DR2, and in this case, the pixel distance of the (2-1)-th unit region SUB1 may be 1. In some embodiments, the (2-2)-th unit region SUB2 illustrated in FIG. 14A may include one pixel PX in the width distance each in the first and second directions DR1 and DR2, and in this case, the pixel distance of the (2-2)-th unit region SUB2 may be 1.

Referring to FIGS. 14A and 14B, after the dividing of the second region AA2 into the two or more second unit regions SUB1 and SUB2 on the second bitmap, the setting of the application amounts of the second resin composition RS2 in the first region AA1 and the second unit regions SUB1 and SUB2 may be performed. The application amount may be set for each of the second unit regions SUB1 and SUB2 such that the application amount of the second resin composition RS2 to be applied to the second unit regions SUB1 and SUB2 is smaller than the application amount of the first resin composition RS1 (see FIG. 13D) to be applied to the first region AA1. For example, the average application amount of the second resin composition RS2 for the second unit regions SUB1 and SUB2 may be set smaller than the application amount of the first resin composition RS1 (see FIG. 13D) for the first regions AA1. The application amount of the second resin composition RS2 for each of the plurality of second unit regions SUB1 and SUB2 may refer to a comparative value if (e.g., when) the application amount of the first resin composition RS1 (see FIG. 13D) to be applied to the first region AA1 is 100 in the applying of the first resin composition RS1 (see FIG. 13D).

The application amount for each of the plurality of second unit regions SUB1 and SUB2 may be set if (e.g., when) the application amount of the first resin composition RS1 to be applied to the first region AA1 is 100 in the applying of the first resin composition RS1. For example, the application amount of the second resin composition RS2 to be applied to the (2-1)-th unit region SUB1 and the application amount of the second resin composition RS2 to be applied to the (2-2)-th unit region SUB2 may each be set.

As shown in Table 2, on the second bitmap, the second region AA2 may be divided into two or more second unit regions SUB1, . . . , and SUBm, and the application amount of the second resin composition RS2 may be set for each of the plurality of second unit regions SUB1, . . . , and SUBm. At this time, the application amount for each of the plurality of second unit regions SUB1, . . . , and SUBm refers to a comparative amount for each of the plurality of second unit regions SUB1, . . . , and SUBm if (e.g., when) the application amount of the first resin composition RS1 (see FIG. 13D) for the first region AA1 is 100.

TABLE 2

| | | | |
|---|---|---|---|
| Second unit region | SUB1 | . . . | SUBm |
| Application amount | Y1 | . . . | Ym |
| Number of pixels (units) | B1 | . . . | Bm |

Referring to Table 2, the second region AA2 may be divided into m second unit regions SUB1, . . . , and SUBm. In Table 2, m may be an integer of 2 or greater. In this specification, the 1st second unit region to the m-th second unit region SUB1, . . . , and SUBm may be referred to as a (2-1)-th unit region to a (2-m)-th unit region, respectively. For example, if (e.g., when) m is 2, the 1st second unit region SUB1 may refer to the (2-1)-th unit region, and the 2nd second unit region SUB2 may refer to the (2-2)-th unit region. Referring to FIG. 14A and Table 2 together, the m second unit regions SUB1, . . . , and SUBm may be sequentially arranged in one direction from the first region AA1 toward an edge portion of the substrate RP. For example, if (e.g., when) m is 2, the (2-1)-th unit region SUB1 and the (2-2)-th unit region SUB2 may be sequentially arranged in one direction from the first region AA1 toward the edge portion of the substrate RP. The m second unit regions SUB1, . . . , and SUBm may each have a closed line shape around (e.g., surrounding) the first region AA1 on a plane.

The m second unit regions SUB1, . . . , and SUBm may each include a set or predetermined number of pixels PX. In Table 2, B1, . . . , and Bm may refer to the number of pixels PX included in the m second unit regions SUB1, . . . , and SUBm, respectively.

Application amounts Y1, . . . , and Ym of the second resin composition RS2 may be set respectively for the m second unit regions SUB1, . . . , and SUBm. At least one among the application amounts Y1, . . . , and Ym of the m second unit regions SUB1, . . . , and SUBm may have a different value. As illustrated in FIG. 14A, in case that the second region AA2 includes two second unit regions, the application amount Y1 of the (2-1)-th unit region SUB1 corresponding to the 1st second unit region and the application amount Y2 of the (2-2)-th unit region SUB2 corresponding to the 2nd second unit region may be different from each other.

In one or more embodiments, if (e.g., when) the application amount of the first resin composition for the first region AA1 is 100, the average application amount of the second resin composition RS2 for the m second unit regions SUB1, . . . , and SUBm may be smaller than the application amount of the first resin composition RS1 (see FIG. 3D) for the first region AA1. For example, if (e.g., when) the application amount of the first resin composition RS1 (see FIG. 13D) for the first region AA1 is 100, the average application amount of the second resin composition RS2 for the m second unit regions SUB1, . . . , and SUBm may be smaller than the application amount of the first resin composition RS1 (see FIG. 13D) for the first region AA1. The average application amount of the second resin composition RS2 for the second unit regions SUB1, . . . , and SUBm may be calculated by Expression 2.

$$[ ( Y 1 \times B 1 ) + … ( Yn \times Bm ) \div ( B 1 + … Bm ) \qquad Expression 2$$

In Expression 2, Y1 . . . . Yn are independently application amounts of the second resin composition RS2 respectively for the 1st second unit region to the m-th second unit region SUB1, . . . , and SUBm if (e.g., when) the application amount of the first resin composition RS1 (see FIG. 13D) to be applied to the first region AA1 is 100. For example, the application amount of the second resin composition RS2 for each of the first second unit region to the m-th second unit region SUB1, . . . , and SUBm may refer to a comparative value if (e.g., when) the application amount of the first resin composition RS1 (see FIG. 13D) to be applied to the first region AA1 is 100.

In Expression 2, B1, . . . , and Bm may independently refer to the number of pixels PX in the 1st second unit region to the m-th second unit region SUB1, . . . , and SUBm, respectively.

In Expression 2, m is an integer of 2 or greater.

Referring to FIGS. 14B and 14C again, the applying of the second resin composition RS2 onto the preliminary adhesion member P-AP may be performed to overlap the second region AA2. In the applying of the second resin composition RS2, the second resin composition RS2 may be applied onto the second region AA2 according to the set application amount. In the applying of the second resin composition RS2, a second inkjet head IHD2 may discharge the second resin composition RS2 on the second region AA2 while moving in the second direction DR2. However, one or more embodiments is not limited thereto, and the second inkjet head IHD2 may also discharge the second resin composition RS2 while moving in the first direction DR1.

The second region AA2 may be divided into two or more second unit regions SUB1 and SUB2, and the second resin composition RS2 may be applied onto each of the second unit regions SUB1 and SUB2 according to the set application amount thereof. For example, the second region AA2 may be divided into the (2-1)-th unit region SUB1 and the (2-2)-th unit region SUB2, the second resin composition RS2 may be applied onto the (2-1)-th unit region SUB1 in a (2-1)-th unit application amount, and the second resin composition RS2 may be applied onto the (2-2)-th unit region SUB2 in a (2-2)-th unit application amount. In one or more embodiments, the (2-1)-th unit application amount may be different from the (2-2)-th unit application amount. For example, the (2-1)-th unit application amount may be larger than the (2-2)-th unit application amount.

After this, in substantially the same method as previously described with reference to FIGS. 13H to 13K, the provided second resin composition RS2 may be cured to form the adhesion member AP (see FIG. 13J).

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display device, the electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display device and/or the electronic device, may be formed on one integrated circuit (IC) chip or on separate IC chips. Further, the one or more suitable components of the device(s) may be implemented on a flexible printed circuit film, a tape carrier package (TCP), a printed circuit board (PCB), or formed on one substrate. Further, the one or more suitable components of the device(s) may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

Hereinafter, referring to examples and comparative examples, the adhesion member according to one or more embodiments and a display device according to one or more embodiments of the disclosure are described in more detail. In some embodiments, the following examples are intended to assist understanding of the disclosure, and the scope of the disclosure is not limited thereto.

### EXAMPLES

### 1. Preparation of Curable Liquid Resin Composition

A resin composition used in each of the examples and comparative examples was prepared according to the mixing ratio listed in Table 3. Composition materials of the resin composition were provided to a heat-resistant and light-blocking container in a weight ratio presented in Table 3, and then Omnirad 819 as a photoinitiator was provided in an amount of about 2 wt % on the basis of 100 wt % amount of the total (entire) resin composition. After this, the provided materials were agitated at about 100 rpm for about 1 hour, using a planetary centrifugal mixer (a product of SHASHIN KAGAKU CO., LTD) at room temperature, to obtain a curable resin composition. A viscosity of the obtained curable resin composition at about 25° C. was about 13 millipascal second (mPa·s). The viscosity of the resin composition was measured using JIS K 2283 at about 25° C., and using a viscometer (TVE-25L, a product of Tokisangyo), the viscosity of a liquid photocurable resin composition was measured at a speed of about 10 rpm.

TABLE 3

| Material | Amount (%) |
|---|---|
| UF-C051 | 3.0 |
| UF-C052 | 3.0 |
| UN6304 | 6.0 |
| 4-HBA | 7.0 |
| 2-EHA | 55.0 |
| THF-A | 15.0 |
| EHDG-AT | 11.0 |

### Abbreviations of Materials Used as Components of the Resin Composition

Reference for each of the components used in the preparation of the resin composition, listed in Table 3, was as follows.
UF-C051: Kyoeisha Chemical Co., Ltd, urethane acrylate
UF-C052: Kyoeisha Chemical Co., Ltd, urethane acrylate
UN6304: Negami Chemical Industrial Co., Ltd, urethane acrylate
4-HBA: Osaka Organic Chemical Industry Ltd., 4-hydroxy butyl acrylate
2-EHA: Toagosei Co., LTD., 2-ethyl hexyl acrylate
THF-A: Kyoeisha Chemical Co., Ltd, tetra hydro furfuryl acrylate
EHDG-AT: Kyoeisha Chemical Co., Ltd, 2-ethyl hexyl-diglycol acrylate

### 2. Manufacture and Evaluation of Adhesion Member

### Creating Application Pattern

In the examples and comparative examples, the application pattern of a first application process was created in a method presented in Table 1 previously described, and listed in Table 4, and the application pattern of a second application process was created in a method presented in Table 2 previously described, and listed in Table 5. In a target substrate, a monochrome bitmap file of about 550 pixels×about 25500 pixels was created, and the application amount for each of the unit regions was set. The resin composition used in each of the first application process and the second application process corresponded to a resin composition prepared through the preparation of the curable liquid resin composition previously described. The setting of each of the unit regions was determined and performed on the basis of the number of pixels at a boundary portion of the bitmap file. The average application amount for the first unit regions SUA1, SUA2, SUA3, and SUA4 was calculated by Expression 1 previously described, and listed in Table 4. In Table 4 and Table 5, the application amount of 100% refers to about 58 gram per square inch (g/inch²), and the application amount of 10% refers to about 5.8 g/inch².

In Table 4, the application amount for the first region AA1 and the application amount and pixel distance values for each of the first unit regions SUA1, SUA2, SUA3, and SUA4 in the first application process were listed, and in Table 5, the application amount for the first region AA1 and the application amount and pixel distance values for each of the second unit regions SUB1 and SUB2 in the second application process were listed. As previously described, the “pixel distance” refers to the number of pixels included in a width distance of each of the unit regions. The total number of pixels included in the first unit regions SUA1, SUA2, SUA3, and SUA4, which are divided on the basis of the pixel distance, was used for the calculation by Expression 1, and the result value was derived therefrom. The number of pixels of the first region AA1 in the first application process corresponds to a value obtained by subtracting the sum of the numbers of pixels in the first unit regions SUA1, SUA2, SUA3, and SUA4 from the total number of pixels. The number of pixels of the first region AA1 in the second application process corresponds to a value obtained by subtracting the sum of the numbers of pixels in the second unit regions SUB1 and SUB2 from the total number of pixels.

### Manufacture of Adhesion Member

To manufacture an adhesion member according to each of the examples and comparative examples, DevicePrinter-CX (MicroJet Technology Co., LTD) with KM1024i (Konica Minolta, Inc) being installed as an inkjet device was used. In a discharge condition where the discharge rate was at least about 5.5 meter per second (m/s) (e.g., or greater) and at most about 6.5 m/s (e.g., or less), the voltage, pulse driving cycle, and temperature were adjusted. The resolution was set to about 360 dots per inch (dpi)×about 5400 dpi, and using the application patterns in Table 4 and Table 5, the application condition was set to the set application amount, and then the application was performed on a PET film (SH86 of SK Chemical) which was washed using an atmospheric pressure plasma treatment instrument.

TABLE 4

| | Application amount (%) of resin | | | | | Result of |
|---|---|---|---|---|---|---|
| | composition/pixel distance in | | | | | calculation |
| Classifi- | first application process | | | | | by |
| cation | AA1 | SUA1 | SUA2 | SUA3 | SUA4 | Expression 1 |
| Example 1 | 70 | 41/8 | 70/4 | — | — | 73 |
| Example 2 | | 41/4 | 0/4 | 70/4 | — | 53 |
| Example 3 | | 60/30 | 43/4 | 65/4 | 0/1 | 81 |
| Comparative | | 41/8 | 70/4 | — | — | 73 |
| Example 1 | | | | | | |
| Comparative | | 41/4 | 0/4 | 70/4 | — | 53 |
| Example 2 | | | | | | |
| Comparative | 25 | 0/1 | — | — | — | 0 |
| Example 3 | | | | | | |

TABLE 5

| | Application amount (%) of resin composition/pixel | | |
|---|---|---|---|
| | distance in second application process | | |
| Classification | AA1 | SUB1 | SUB2 |
| Example 1 | 0 | 40/4 | 40/4 |
| Example 2 | | 40/4 | 40/4 |
| Example 3 | | 100/2 | 0/1 |
| Comparative | Second application process not included | | |
| Example 1 | | | |
| Comparative | Second application process not included | | |
| Example 2 | | | |
| Comparative | 44 | 0/1 | — |
| Example 3 | | | |

### Evaluation on Shape of Coated Film on Adhesion Member

A shape of a coated film after the curing of the adhesion member, according to each of the Examples 1 to 3 and Comparative Examples 1 to 3, was evaluated, and the results were listed in Table 6. The shape of the coated film on the adhesion member according to each of the Examples 1 to 3 and Comparative Examples 1 to 3 was evaluated in a method as follows.

The shape of the coated film of a photocurable resin composition applied onto a PET film was measured using a Keyence laser microscope (VK-X3000). A distance in the horizontal direction from an edge of the formed adhesion member to a peak part on a boundary of the adhesion member was measured, and listed in Table 6. The result value, obtained from the measurement of the distance in the horizontal direction, was rounded to the first decimal place, measuring an “edge-peak distance”.

TABLE 6

| Classification | Edge-peak distance |
|---|---|
| Example 1 | 310 μm |
| Example 2 | 450 μm |
| Example 3 | 580 μm |
| Comparative Example 1 | 2030 μm |
| Comparative Example 2 | 2100 μm |
| Comparative Example 3 | 800 μm |

Referring to the results listed in Table 6, it may be seen that the “edge-peak distance” values, measured according to Example 1 to Example 3, were at most about 600 micrometer (μm) (e.g., or less). In comparison, according to Comparative Example 1 to Comparative Example 3, it may be seen that the “edge-peak distance” values were greater than about 600 μm. Comparing Examples 1 and 2 with Comparative Examples 1 and 2, it may be seen that the “edge-peak distance” values according to Comparative Examples 1 and 2 significantly increased compared to those of Examples 1 and 2. In Comparative Example 1, unlike Example 1, the second application process was not included, and in Comparative Example 2, unlike Example 2, the second application process was not included. In case of not including the second application process, like in Comparative Examples 1 and 2, a region with increased thickness around the boundary of the adhesion member is formed more inward, so that the length of a slope, which is a horizontal distance from the edge of the adhesion member to the peak part, may increase. In an inkjet process, the film thickness may decrease gradually toward the boundary of an ink-discharging region, and due to dispersion of a solution around the boundary, the thickness may increase again, thereby forming a thickness-increasing region. Accordingly, the formed thickness-increasing region may correspond to the peak part. Like in Comparative Examples 1 and 2, when the thickness-increasing region is formed more inward, the curved slope of the adhesion member may be visible from the outside of the display device, thereby causing deterioration of movie quality. In comparison, according to the examples, because two cycles of application processes were performed in the process of applying the resin composition through inkjet printing, and the application amount of the resin composition to be provided was controlled or selected according to the region, the length of the slope formed on the edge portion of an adhesion layer may decrease, thereby improving durability and reliability of the display device.

Comparing Examples 1 to 3 with Comparative Example 3, it may be seen that the “edge-peak distance” value according to Comparative Example 3 increased compared to those of the Examples 1 to 3. Comparative Example 3 corresponds to the case where the resin composition was applied only to the first region AA1 both (e.g., simultaneously) in the first application process and the second application process. In Comparative Example 3, because the application amount provided around the boundary of the substrate is relatively small in the two cycles of application processes, the edge-peak distance” may decrease, compared to Comparative Examples 1 and 2 where the second application process was not included. However, even though the resin composition was applied to a central portion of the substrate other than a partial region around the boundary of the substrate, it was not enough to control flow of the resin composition, and accordingly, it can be seen that the “edge-peak distance” according to Comparative Example 3 increased compared to those of the Examples 1 to 3.

The liquid resin composition applied to the substrate may be dispersed on the substrate and may form a film thickness. Accordingly, the resin composition provided to the target substrate flows also in a direction toward the outside of the substrate from the boundary portion of the substrate, so that the thickness at the boundary portion of the substrate may become uneven, and the border shape of the adhesion member may become unclear. According to the disclosure, because two cycles of application processes were performed in the process of applying the resin composition through inkjet printing, and the application amount of the resin composition to be provided was controlled or selected according to the region, the adhesion member may have a good or suitable distribution of film thickness of the adhesion member at the boundary portion of the target substrate. In some embodiments, without using an additional structure, the thickness shape of the adhesion member at the boundary portion may be controlled or selected easily, thereby improving process efficiency.

In a manufacturing method for a display device according to one or more embodiments, it may be possible to form a thin film having a good or suitable distribution of film thickness around a boundary of a target substrate.

An electronic device according to one or more embodiments may include an adhesion member in which a shape around a boundary is controlled or selected, thereby exhibiting excellent or suitable adhesion reliability.

In the preceding, description has been made with reference to one or more embodiments of the disclosure, but those skilled or of ordinary skill in the art may understand that one or more suitable modifications and changes may be made to the disclosure insofar as such modifications and changes do not depart from the spirit and technical scope of the disclosure set forth in the following claims.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

Therefore, the technical scope of the disclosure is not to be limited to the contents stated in the detailed description of the specification, but should be determined by the claims and equivalents thereof.

1. A method comprising:
applying a substrate on a stage, the substrate comprising a first region and a second region around the first region; and
forming an adhesion member on the substrate,
wherein,
the forming of the adhesion member comprises:
applying a first resin composition onto the substrate to overlap the first region and the second region;
providing a first light to cure the first resin composition;
applying a second resin composition onto a cured first resin composition to overlap the second region; and
providing a second light to cure the second resin composition,
wherein, each of the first resin composition and the second resin composition has a viscosity of at least about 10 millipascal second (mPa·s) and at most about 30 mPa·s at about 25° C., and
wherein the method is a method for manufacturing a display device.

2. The method of claim 1, wherein, in the applying of the first resin composition,
a first application amount of the first resin composition is to be applied to the first region, and is larger than a second application amount of the first resin composition to be applied to the second region.

3. The method of claim 1, wherein the second region is divided into at least two first unit regions each having a different application amount of the first resin composition.

4. The method of claim 3, wherein the second region is divided into:
a (1-1)-th unit region being adjacent to the first region and around the first region; and
a (1-2)-th unit region being spaced apart from the first region and around the (1-1)-th unit region, and
wherein the (1-1)-th unit region is between the first region and the (1-2)-th unit region, and
wherein an application amount of the first resin composition to be applied to the (1-1)-th unit region is less than an application amount of the first resin composition to be applied to the (1-2)-th unit region.

5. The method of claim 3, wherein, before the applying of the first resin composition, the forming of the adhesion member further comprises:
forming the substrate into a bitmap comprising m pixels in a first direction and g pixels in a second direction crossing the first direction;
dividing the second region into the at least two first unit regions on the bitmap; and
setting an application amount of the first resin composition for each of the first region and the first unit regions, and
wherein an average application amount of the first resin composition for the first unit regions is calculated by Expression 1, and is at least about 50 and at most about 85:
$$[ ( X 1 \times A 1 ) \underline{+ …} [ [ … ] ] ( Xn \times An ) ] \div ( A 1 + … An ) \qquad Expression 1$$
wherein, in Expression 1,
X1 to Xn are each independently an application amount of the first resin composition for a 1st first unit region to an n-th first unit region,
an application amount of the first resin composition to be applied to the first region is 100, and n is an integer of 2 or greater, and
A1 to An are each independently a number of pixels in the 1st first unit region to the n-th first unit region, and n is an integer of 2 or greater.

6. The method of claim 1, wherein, before the applying of the second resin composition, the forming of the adhesion member further comprises:
forming the substrate into a bitmap comprising p pixels in a first direction, and q pixels in a second direction crossing the first direction;
dividing the second region into at least two second unit regions on the bitmap; and
setting an application amount of the second resin composition for each of the second unit regions.

7. The method of claim 6, wherein each second unit region comprises:
a (2-1)-th unit region being adjacent to the first region and around the second region; and
a (2-2)-th unit region being spaced from the first region, and around the (2-1)-th unit region,
wherein the (2-1)-th unit region is between the first region and the (2-2)-th unit region, and
wherein an application amount of the second resin composition to be applied to the (2-1)-th unit region is different from an application amount of the second resin composition to be applied to the (2-2)-th unit region.

8. The method of claim 7, wherein the application amount of the second resin composition to be applied to the (2-1)-th unit region is larger than the application amount of the second resin composition to be applied to the (2-2)-th unit region.

9. The method of claim 1, wherein the adhesion member comprises a peak part which overlaps the second region, and at which a height from a lower surface of the adhesion member to an upper surface of the adhesion member is maximum in a thickness direction, and
a horizontal distance from an edge of the adhesion member to the peak part is at least about 300 micrometer (μm) and at most about 600 μm.

10. The method of claim 1, wherein, in the forming of the adhesion member, a temperature at the stage is at least about 20° C. and at most about 30° C.

11. The method of claim 1, wherein the first resin composition and the second resin composition are applied through inkjet printing.

12. The method of claim 1, wherein the second region has a width of at most about 3 millimeter (mm).

13. The method of claim 1, wherein, in the applying of the second resin composition, the second resin composition applied onto the substrate does not overlap the first region.

14. A method comprising:
preparing a display panel comprising a first region and a second region around the first region;
forming an adhesion member on the display panel utilizing an inkjet process; and
bonding a window onto the display panel through the adhesion member,
wherein,
the forming of the adhesion member comprises:
applying a first resin composition onto the display panel;
curing the first resin composition to form a preliminary adhesion member;
applying a second resin composition onto the preliminary adhesion member along an edge of the preliminary adhesion member; and
curing the second resin composition,
wherein, each of the first resin composition and the second resin composition has a viscosity of at least about 10 mPa·s and at most about 30 mPa·s at about 25° C., and
wherein the method is a method for manufacturing a display device.

15. The method of claim 14, wherein, in the applying of the first resin composition,
an application amount of the first resin composition is sprayed from an inkjet head,
the first resin composition is applied onto the first region in a first application amount, and
the first resin composition is applied onto the second region in a second application amount that is different from the first application amount.

16. The method of claim 14, wherein, before the applying of the first resin composition, the forming of the adhesion member further comprises:
dividing the second region into at least two first unit regions each having a different application amount of the first resin composition; and
setting an application amount of the first resin composition for each of the first region and the first unit regions, and
wherein, in the applying of the first resin composition onto the display panel, the first resin composition is applied to the first region and the first unit regions according to a set application amount.

17. The method of claim 14, wherein the edge of the preliminary adhesion member corresponds to the second region of the display panel.

18. An electronic device comprising:
a display panel comprising a first region and a second region around the first region;
a window on the display panel; and
an adhesion member between the display panel and the window, and comprising a resin composition having a viscosity of at least about 10 mPa·s and at most about 30 mPa·s about 25° C.,
wherein,
the adhesion member comprises a peak part which overlaps the second region, and at which a height from a lower surface of the adhesion member to an upper surface of the adhesion member is maximum in a thickness direction, and
a horizontal distance from an edge of the adhesion member to the peak part is at least about 300 μm and at most about 600 μm.

19. The electronic device of claim 18, wherein the electronic device is selected from among a large-size display device comprising a television, a monitor, and an outdoor billboard, and a small- and medium-size display device comprising a personal computer, a laptop computer, a personal digital assistant, a display device for a vehicle, a game console, a portable electronic device, a camera, and a combination thereof.

20. The electronic device of claim 19, wherein the electronic device further comprises at least one of a processor, a memory, or a power module.
